(19) United States
(12) Patent Application Publication
(10) Pub. No.: US 2025/0351642 A1
(43) Pub. Date: Nov. 13, 2025

(54) LIGHT EMITTING ELEMENT, DISPLAY DEVICE INCLUDING THE SAME, METHOD OF MANUFACTURING THE DISPLAY DEVICE, AND ELECTRONIC DEVICE INCLUDING THE DISPLAY DEVICE

(71) Applicant: Samsung Display Co., LTD., Yongin-si (KR)

(72) Inventors: Youngchul Sim, Yongin-si (KR); KWANJAE LEE, Yongin-si (KR)

(21) Appl. No.: 19/015,416

(22) Filed: Jan. 9, 2025

(30) Foreign Application Priority Data
May 10, 2024 (KR) 10-2024-0061810

(51) Int. Cl. H10H 29/32; H10H 29/01; H10H 29/49

(52) U.S. Cl. CPC H10H 29/32; H10H 29/012; H10H 29/0364; H10H 29/49

(57) ABSTRACT

A light emitting element is disclosed. The light emitting element may include: a first light emitting cell in a first pixel area, a second light emitting cell in the first pixel area on the first light emitting cell, and a third light emitting cell in a second pixel area spaced and/or apart (or spaced part or separated) from the first pixel area in a plan view. The first light emitting cell may be to emit first light. The second light emitting cell may be to emit second light having a wavelength that may be different from a wavelength of the first light. The third light emitting cell may be to emit third light having a wavelength that may be different from each of the wavelength of the first light and the wavelength of the second light.

### CROSS-REFERENCE TO RELATED APPLICATION

The present application claims priority to and the benefit of Korean Patent Application No. 10-2024-0061810, filed on May 10, 2024, in the Korean Intellectual Property Office, the entire content of which is incorporated herein by reference.

### BACKGROUND

### 1. Field

One or more embodiments of the present disclosure relate to a light emitting element, a display device including the light emitting element, a method of manufacturing the display device, and an electronic device including the display device. One or more embodiments of the present disclosure relate to a light emitting element including a semiconductor layer, a display device including the light emitting element, a method of manufacturing the display device, and an electronic device including the display device.

### 2. Description of the Related Art

With the development of information technology, the importance of a display device acting or serving as a connection medium between users and information has emerged. For example, the use of a display device, such as liquid crystal display devices, organic light emitting display devices, plasma display devices, micro light-emitting diode (LED) display devices, and/or the like, is increasing.

The micro LED display device may include an inorganic light emitting element. The inorganic light emitting element is a semiconductor light emitting element that converts current into light and has relatively high light conversion efficiency. Additionally, the inorganic light emitting element is relatively semi-permanent (e.g., has a long lifespan and/or is highly durable) and/or environmentally friendly, with low energy consumption.

### SUMMARY

One or more aspects of embodiments of the present disclosure are directed toward a light emitting element that is produced through (with) a suitably simplified or modified manufacturing process.

One or more aspects of embodiments of the present disclosure are directed toward a display device that includes the light emitting element.

One or more aspects of embodiments of the present disclosure are directed toward a method of manufacturing the display device.

One or more aspects of embodiments of the present disclosure are directed toward an electronic device including the display device.

Additional aspects will be set forth in part in the description which follows and, in part, will be apparent from the description, or may be learned by practice of the presented embodiments of the disclosure.

A light emitting element according to one or more embodiments may include a first light emitting cell arranged (or provided) in a first pixel area, a second light emitting cell arranged (or provided) in the first pixel area on the first light emitting cell, and/or a third light emitting cell arranged (or provided) in a second pixel area spaced and/or apart (e.g., spaced apart or separated) from the first pixel area in a plan view.

In one or more embodiments, the first light emitting cell may be to emit first light.

In one or more embodiments, the second light emitting cell may be to emit second light having a wavelength different from a wavelength of the first light.

In one or more embodiments, the third light emitting cell may be to emit third light having a wavelength different from each of the wavelength of the first light and the wavelength of the second light.

In one or more embodiments, the third light emitting cell may be arranged (or provided) on the first light emitting cell.

In one or more embodiments, the light emitting element may further include a fourth light emitting cell arranged (or provided) in the second pixel area, arranged (or provided) under the third light emitting cell, and emitting the first light.

In one or more embodiments, the first light emitting cell may include a 1-1 semiconductor layer, a first active layer arranged (or provided) on the 1-1 semiconductor layer, and/or a 1-2 semiconductor layer arranged (or provided) on the first active layer.

In one or more embodiments, the second light emitting cell may include a 2-1 semiconductor layer, a second active layer arranged (or provided) on the 2-1 semiconductor layer, and/or a 2-2 semiconductor layer arranged (or provided) on the second active layer.

In one or more embodiments, each of the 1-1 semiconductor layer and the 2-2 semiconductor layer may include a negative-type (n-type or n-kind) semiconductor layer.

In one or more embodiments, each of the 1-2 semiconductor layer and the 2-1 semiconductor layer may include a positive-type (p-type or p-kind) semiconductor layer.

In one or more embodiments, the light emitting element may further include a connection electrode electrically connected to (or coupled to) each of the 1-2 semiconductor layer and the 2-1 semiconductor layer.

A light emitting element according to one or more embodiments may include a first light emitting cell arranged (or provided) in a first pixel area and emitting first light, a second light emitting cell arranged (or provided) in the first pixel area on the first light emitting cell and emitting second light having a wavelength different from a wavelength of the first light, and/or a third light emitting cell arranged (or provided) in a second pixel area spaced and/or apart (e.g., spaced apart or separated) from the first pixel area in a plan view and emitting third light having a wavelength different from each of the wavelength of the first light and the wavelength of the second light.

In one or more embodiments, the first light emitting cell may include a 1-1 semiconductor layer including an n-type semiconductor layer, a first active layer arranged (or provided) on the 1-1 semiconductor layer, and/or a 1-2 semiconductor layer arranged (or provided) on the first active layer and including a p-type semiconductor layer.

In one or more embodiments, the second light emitting cell may include a 2-1 semiconductor layer including a p-type semiconductor layer, a second active layer arranged (or provided) on the 2-1 semiconductor layer, and/or a 2-2 semiconductor layer arranged (or provided) on the second active layer and including an n-type semiconductor layer.

In one or more embodiments, the third light emitting cell may include a 3-1 semiconductor layer including a p-type semiconductor layer, a third active layer arranged (or provided) on the 3-1 semiconductor layer, and/or a 3-2 semiconductor layer arranged (or provided) on the third active layer and including an n-type semiconductor layer.

In one or more embodiments, the third light emitting cell may be arranged (or provided) on the first light emitting cell.

In one or more embodiments, the light emitting element may further include a connection electrode electrically connected to (or coupled to) each of the 1-2 semiconductor layer and the 2-1 semiconductor layer.

In one or more embodiments, the light emitting element may further include a fourth light emitting cell arranged (or provided) in the second pixel area, arranged (or provided) under the third light emitting cell, and emitting the first light.

In one or more embodiments, the fourth light emitting cell may include a 4-1 semiconductor layer including an n-type semiconductor layer, a fourth active layer arranged (or provided) on the 4-1 semiconductor layer, and/or a 4-2 semiconductor layer arranged (or provided) on the fourth active layer and including a p-type semiconductor layer.

In one or more embodiments, the first light emitting cell may be continuously (e.g., substantially continuously) arranged (or provided) over the first pixel area and the second pixel area.

A light emitting element according to one or more embodiments may include a first light emitting cell arranged (or provided) in a first pixel area and emitting first light, a second light emitting cell arranged (or provided) in the first pixel area on the first light emitting cell and emitting second light having a wavelength different from a wavelength of the first light, and/or a third light emitting cell arranged (or provided) in a second pixel area spaced and/or apart (e.g., spaced apart or separated) from the first pixel area in a plan view and emitting third light having a wavelength different from each of the wavelength of the first light and the wavelength of the second light.

In one or more embodiments, the first light emitting cell may include a 1-1 semiconductor layer including a p-type semiconductor layer, a first active layer arranged (or provided) on the 1-1 semiconductor layer, and/or a 1-2 semiconductor layer arranged (or provided) on the first active layer and including an n-type semiconductor layer.

In one or more embodiments, the second light emitting cell may include a 2-1 semiconductor layer including an n-type semiconductor layer, a second active layer arranged (or provided) on the 2-1 semiconductor layer, and/or a 2-2 semiconductor layer arranged (or provided) on the second active layer and including a p-type semiconductor layer.

In one or more embodiments, the third light emitting cell may include a 3-1 semiconductor layer including an n-type semiconductor layer, a third active layer arranged (or provided) on the 3-1 semiconductor layer, and/or a 3-2 semiconductor layer arranged (or provided) on the third active layer and including a p-type semiconductor layer.

In one or more embodiments, the third light emitting cell may be arranged (or provided) on the first light emitting cell.

In one or more embodiments, the light emitting element may further include a connection electrode electrically connected to (or coupled to) each of the 1-2 semiconductor layer and the 2-1 semiconductor layer.

In one or more embodiments, the light emitting element may further include a fourth light emitting cell arranged (or provided) in the second pixel area, arranged (or provided) under the third light emitting cell, and emitting the first light.

In one or more embodiments, the fourth light emitting cell may include a 4-1 semiconductor layer including a p-type semiconductor layer, a fourth active layer arranged (or provided) on the 4-1 semiconductor layer, and/or a 4-2 semiconductor layer arranged (or provided) on the fourth active layer and including an n-type semiconductor layer.

A display device according to one or more embodiments may include a circuit board and a light emitting element arranged (or provided) on the circuit board.

In one or more embodiments, the light emitting element may include a first light emitting cell arranged (or provided) in a first pixel area, a second light emitting cell arranged (or provided) in the first pixel area on the first light emitting cell, and/or a third light emitting cell arranged (or provided) in a second pixel area spaced and/or apart (e.g., spaced apart or separated) from the first pixel area in a plan view.

In one or more embodiments, the first light emitting cell may be to emit first light.

In one or more embodiments, the second light emitting cell may be to emit second light having a wavelength different from a wavelength of the first light.

In one or more embodiments, the third light emitting cell may be to emit third light having a wavelength different from each of the wavelength of the first light and the wavelength of the second light.

In one or more embodiments, the third light emitting cell may be arranged (or provided) on the first light emitting cell.

In one or more embodiments, the first light emitting cell may include a 1-1 semiconductor layer, a first active layer arranged (or provided) on the 1-1 semiconductor layer, and/or a 1-2 semiconductor layer arranged (or provided) on the first active layer.

In one or more embodiments, the second light emitting cell may include a 2-1 semiconductor layer, a second active layer arranged (or provided) on the 2-1 semiconductor layer, and/or a 2-2 semiconductor layer arranged (or provided) on the second active layer.

In one or more embodiments, each of the 1-1 semiconductor layer and the 2-2 semiconductor layer may include an n-type semiconductor layer.

In one or more embodiments, each of the 1-2 semiconductor layer and the 2-1 semiconductor layer may include a p-type semiconductor layer.

In one or more embodiments, the circuit board may include a first electrode, a second electrode, and/or a third electrode.

In one or more embodiments, the 1-2 semiconductor layer and the 2-1 semiconductor layer may be electrically connected to (or coupled to) the first electrode.

In one or more embodiments, the 1-1 semiconductor layer may be electrically connected to (or coupled to) the second electrode.

In one or more embodiments, the 2-2 semiconductor layer may be electrically connected to (or coupled to) the third electrode.

In one or more embodiments, the 2-2 semiconductor layer may be electrically connected to (or coupled to) the third electrode through a connection electrode penetrating at least a portion of each of the first light emitting cell and the second light emitting cell.

A method of manufacturing a display device may include forming a first light emitting cell arranged (or provided) in a first pixel area on the circuit board, forming a second light emitting cell arranged (or provided) in the first pixel area on a first growth substrate, forming a third light emitting cell arranged (or provided) in a second pixel area spaced and/or apart (e.g., spaced apart or separated) from the first pixel area in a plan view on the first growth substrate, and/or attaching the second light emitting cell and the third light emitting cell on the first light emitting cell.

In one or more embodiments, the first light emitting cell may be to emit first light.

In one or more embodiments, the second light emitting cell may be to emit second light having a wavelength different from a wavelength of the first light.

In one or more embodiments, the third emitting cell may be to emit third light having a wavelength different from each of the wavelength of the first light and the wavelength of the second light.

In one or more embodiments, the forming of the first light emitting cell may include forming a first semiconductor layer on the second growth substrate, forming an active layer on the first semiconductor layer, forming a second semiconductor layer on the active layer, removing the second growth substrate, and/or removing a portion of the first semiconductor layer, the active layer, and/or the second semiconductor layer not overlapping the first pixel area in the plan view on the circuit board.

In one or more embodiments, the method may further include forming a first connection electrode penetrating at least a portion of the first light emitting cell and electrically connected to (or coupled to) an electrode included in the circuit board and/or forming a second connection electrode penetrating at least a portion of the second light emitting cell and electrically connected to (or coupled to) the first connection electrode.

In one or more embodiments, the forming of the second light emitting cell may include forming a preliminary insulating (e.g., electrically insulating) layer on the first growth substrate, forming an insulating (e.g., electrically insulating) layer by removing a portion of the preliminary insulating (e.g., electrically insulating) layer overlapping the first pixel area and/or the second pixel area, forming a first semiconductor layer in the first pixel area on the first growth substrate, forming an active layer on the first semiconductor layer, and/or forming a second semiconductor layer on the active layer.

In one or more embodiments, the second semiconductor layer may be electrically connected to (or coupled to) the second connection electrode.

An electronic device according to one or more embodiments may include a circuit board, a light emitting element arranged (or provided) on the circuit board, and a memory device configured to store data.

In one or more embodiments, the light emitting element may include a first light emitting cell arranged (or provided) in a first pixel area, a second light emitting cell arranged (or provided) in the first pixel area on the first light emitting cell, and/or a third light emitting cell arranged (or provided) in a second pixel area spaced and/or apart (e.g., spaced apart or separated) from the first pixel area in a plan view.

In one or more embodiments, the first light emitting cell may be to emit first light.

In one or more embodiments, the second light emitting cell may be to emit second light having a wavelength different from a wavelength of the first light.

In one or more embodiments, the third light emitting cell may be to emit third light having a wavelength different from each of the wavelength of the first light and the wavelength of the second light.

A display device according to one or more embodiments may include a circuit board and a light emitting element. The light emitting element may include a first light emitting cell arranged (or provided) in a first pixel area, a second light emitting cell arranged (or provided) in the first pixel area on the first light emitting cell, and/or a third light emitting cell arranged (or provided) in a second pixel area spaced and/or apart (e.g., spaced apart or separated) from the first pixel area in a plan view. The first light emitting cell may be to emit first light. The second light emitting cell may be to emit second light having a wavelength different from a wavelength of the first light. The third light emitting cell may be to emit third light having a wavelength different from each of the wavelength of the first light and the wavelength of the second light.

A method of manufacturing the display device may include forming a first light emitting cell arranged (or provided) in a first pixel area on the circuit board, forming a second light emitting cell arranged (or provided) in the first pixel area on a first growth substrate, forming a third light emitting cell arranged (or provided) in a second pixel area spaced and/or apart (e.g., spaced apart or separated) from the first pixel area in a plan view on the first growth substrate, and/or attaching the second light emitting cell and/or the third light emitting cell on the first light emitting cell. The first light emitting cell may be to emit first light. The second light emitting cell may be to emit second light having a wavelength different from a wavelength of the first light. The third light emitting cell may be to emit third light having a wavelength different from each of the wavelength of the first light and the wavelength of the second light.

For example, a display device, in which a red, green, and blue (RGB) full-color system is implemented, may be manufactured through a single bonding process of attaching the second light emitting cell and/or the third light emitting cell on the first light emitting cell. Accordingly, a manufacturing process of the display device may be suitably simplified or modified.

### BRIEF DESCRIPTION OF THE DRAWINGS

Illustrative, non-limiting embodiments of the present disclosure will be more clearly understood from the following more detailed description in conjunction with the accompanying drawings.

FIG. 1 is a plan view illustrating a display device according to one or more embodiments.

FIG. 2 is a cross-sectional view illustrating the display device of FIG. 1 taken along the line 1-11.

FIG. 3 is a cross-sectional view illustrating a light emitting element included in the display device of FIG. 2.

FIG. 4 is a plan view illustrating a display area included in the display device of FIG. 1.

FIGS. 5-33 are cross-sectional views illustrating a method of manufacturing the display device of FIG. 2.

FIG. 34 is a cross-sectional view illustrating a display device according to one or more embodiments.

FIG. 35 is a cross-sectional view illustrating a display device according to one or more embodiments.

FIG. 36 is a block diagram illustrating an electronic device according to one or more embodiments.

FIG. 37 is a diagram illustrating an example in which the electronic device of FIG. 36 is implemented as a smart phone.

### DETAILED DESCRIPTION

Hereinafter, display devices in accordance with one or more embodiments of the present disclosure will be described in more detail with reference to the accompanying drawings. The same reference numerals are used for substantially the same components in the drawings, and redundant descriptions of substantially the same components will not be provided.

As utilized herein, the singular forms “a,” “an,” and “the” are intended to include the plural forms as well, unless the context clearly indicates otherwise. Further, the utilization of “may” when describing embodiments of the present disclosure refers to “one or more embodiments of the present disclosure”.

In the context of the present disclosure and unless otherwise defined, the terms “use,” “using,” and “used” may be considered synonymous with the terms “utilize,” “utilizing,” and “utilized,” respectively.

It will be understood that, although the terms “first,” “second,” “third,” and/or the like, may be used herein to describe one or more elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms, “below” and “under,” may encompass both an orientation of above and below. The device may be otherwise oriented (e.g., rotated 90 degrees or at other orientations) and the spatially relative descriptors used herein should be interpreted accordingly.

It will be understood that if (e.g., when) an element or layer is referred to as being “on,” “connected to,” or “coupled to” another element or layer, it can be directly on, connected to, or coupled to the other element or layer, or one or more intervening elements or layers may be present. In addition, it will also be understood that if (e.g., when) an element or layer is referred to as being “between” two elements or layers, it can be the only element or layer between the two elements or layers, or one or more intervening elements or layers may also be present.

Throughout the specification, the terms, “include” or “have,” are intended to specify the presence of stated features, integers, steps, operations, constituent elements, components and/or a (e.g., any suitable) combination thereof, but do not preclude the presence or addition of one or more other features, integers, steps, operations, constituent elements, components, and/or groups thereof. Therefore, unless explicitly described to the contrary, the term, “include,” and variations, such as “includes” or “including,” will be understood to imply the inclusion of stated elements but not the exclusion of any other suitable elements.

As used herein, the term “and/or” includes any and all combinations of one or more of the associated listed items. Expressions such as “at least one of,” when preceding a list of elements, modify the entire list of elements and do not modify the individual elements of the list.

Unless otherwise defined, all terms (including technical and scientific terms) used herein have substantially the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

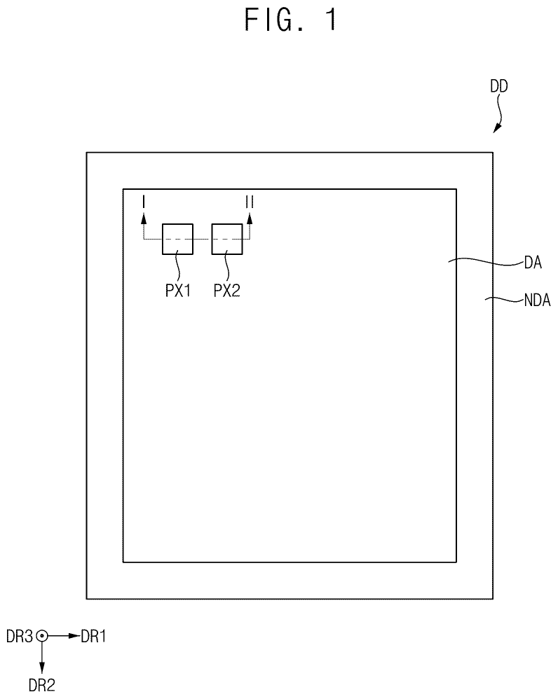

FIG. 1 is a plan view illustrating a display device according to one or more embodiments.

Referring to FIG. 1, a display device DD according to one or more embodiments may include a display area DA and a non-display area NDA.

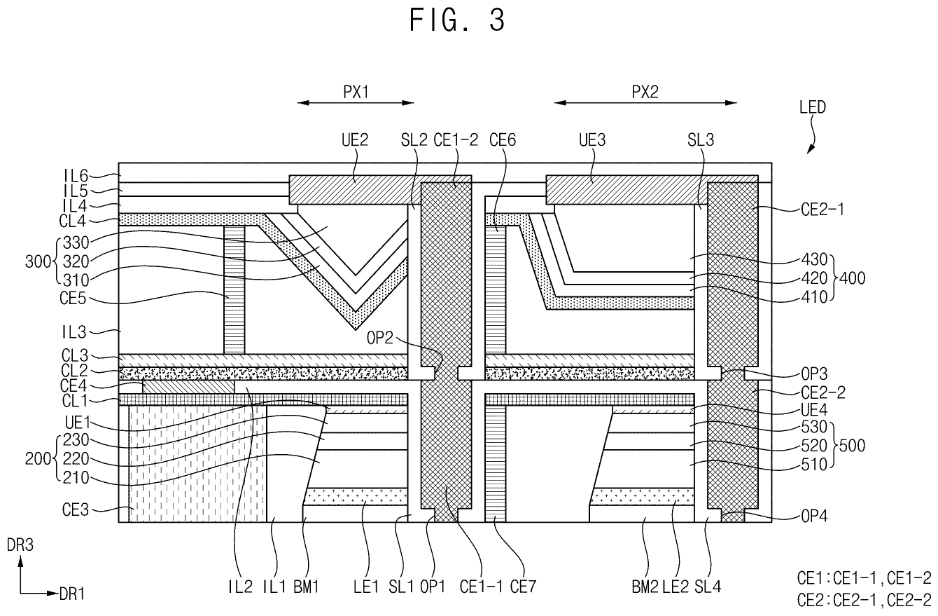

A plurality of pixel areas may be arranged (or provided) in the display area DA. For example, a first pixel area PX1 and/or a second pixel area PX2 may be arranged (or provided) in the display area DA. Each of the first pixel area PX1 and the second pixel area PX2 may be an area in which light emitted from a light emitting element (for example, a light emitting element LED of FIG. 3) is emitted to an outside of the display device DD.

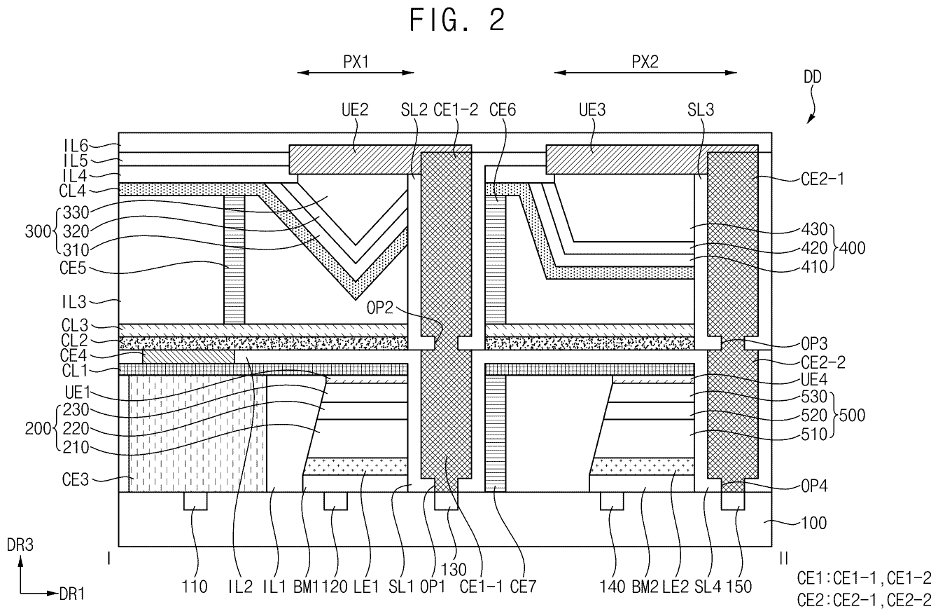

For example, the first pixel area PX1 may be an area in which light emitted from a first light emitting cell (e.g., a first light emitting cell 200 of FIG. 2) and/or a second light emitting cell (e.g., a second light emitting cell 300 of FIG. 2) is emitted to the outside of the display device DD. For example, the second pixel area PX2 may be an area in which light emitted from a third light emitting cell (e.g., a third light emitting cell 400 of FIG. 2) and/or a fourth light emitting cell (e.g., a fourth light emitting cell 500 of FIG. 2) is emitted to the outside of the display device DD.

The plurality of pixel areas may be repeatedly arranged (or provided) along a first direction DR1 and/or a second direction DR2 crossing the first direction DR1. For example, the second pixel area PX2 may be spaced and/or apart (e.g., spaced apart or separated) from the first pixel area PX1 in a plan view. For example, the second pixel area PX2 may be spaced and/or apart (e.g., spaced apart or separated) from the first pixel area PX1 in the first direction DR1.

The non-display area NDA may be arranged (or provided) around (e.g., surround) the display area DA. For example, the non-display area NDA may be around (e.g., surround) at least a portion of the display area DA. A driver may be arranged (or provided) in the non-display area NDA. The driver may provide a signal and/or a voltage to the plurality of pixel areas. For example, the driver may include a data driver, a gate driver, and/or the like. The non-display area NDA may not display an image.

In one or more embodiments, the first direction DR1 and the second direction DR2 crossing the first direction DR1 may be defined. For example, the second direction DR2 may be normal (e.g., substantially perpendicular) to the first direction DR1. However, embodiments of the present disclosure are not limited thereto, and the second direction DR2 may form (or provide) an acute angle or an obtuse angle with the first direction DR1. In addition, a third direction DR3 crossing a plane formed (or provided) by the first direction DR1 and/or the second direction DR2 may be defined. For example, the third direction DR3 may be normal (e.g., substantially perpendicular) to the plane formed (or provided) by the first direction DR1 and/or the second directions DR2. However, embodiments of the present disclosure are not limited thereto, and the third direction DR3 may form (or provide) an acute angle or an obtuse angle with the plane formed (or provided) by the first direction DR1 and/or the second direction DR2.

FIG. 2 is a cross-sectional view illustrating the display device of FIG. 1 taken along the line 1-11. FIG. 3 is a cross-sectional view illustrating a light emitting element included in the display device of FIG. 2.

Referring to FIGS. 2 and 3, the display device DD may include a circuit board 100 and/or a light emitting element LED.

The circuit board 100 may include a circuit element controlling the light emitting element LED. For example, the circuit board 100 may include a circuit element controlling each of the first light emitting cell 200, the second light emitting cell 300, the third light emitting cell 400, and the fourth light emitting cell 500. For example, the circuit board 100 may include a thin-film-transistor (TFT), a p-channel metal-oxide semiconductor (PMOS), an n-channel metal-oxide semiconductor (NMOS), a complementary metal-oxide-semiconductor (CMOS) structure, and/or the like.

In one or more embodiments, the circuit board 100 may include a first electrode 110, a second electrode 120, a third electrode 130, a fourth electrode 140, and/or a fifth electrode 150. The second electrode 120 may be spaced and/or apart (e.g., spaced apart or separated) from the first electrode 110 in the first direction DR1. The third electrode 130 may be spaced and/or apart (e.g., spaced apart or separated) from the second electrode 120 in the first direction DR1. The fourth electrode 140 may be spaced and/or apart (e.g., spaced apart or separated) from the third electrode 130 in the first direction DR1. The fifth electrode 150 may be spaced and/or apart (e.g., spaced apart or separated) from the fourth electrode 140 in the first direction DR1.

For example, each of the first electrode 110, the second electrode 120, the third electrode 130, the fourth electrode 140, and the fifth electrode 150 may include a metal, an alloy, a metal nitride, a conductive (e.g., electrically conductive) metal oxide, a transparent conductive (e.g., electrically conductive) material, and/or the like. These materials may be used alone or in (e.g., any suitable) combination with each other.

The light emitting element LED may be arranged (or provided) on the circuit board 100. The light emitting element LED may include a first light emitting cell 200, a second light emitting cell 300, a third light emitting cell 400, a fourth light emitting cell 500, a first insulating layer IL1, a second insulating layer IL2, a third insulating layer IL3, a fourth insulating layer IL4, a fifth insulating layer IL5, a sixth insulating layer IL6, a first connection electrode CE1, a second connection electrode CE2, a third connection electrode CE3, a fourth connection electrode CE4, a fifth connection electrode CE5, a sixth connection electrode CE6, a seventh connection electrode CE7, a first conductive layer CL1, a second conductive layer CL2, a third conductive layer CL3, a fourth conductive layer CL4, a first lower metal layer LE1, a second lower metal layer LE2, a first adhesive layer BM1, a second adhesive layer BM2, a first upper metal layer UE1, a second upper metal layer UE2, a third upper metal layer UE3, a fourth upper metal layer UE4, a first side insulating layer SL1, a second side insulating layer SL2, a third side insulating layer SL3, and/or a fourth side insulating layer SL4.

The first light emitting cell 200 may be arranged (or provided) on the circuit board 100. The first light emitting cell 200 may be arranged (or provided) in the first pixel area PX1. For example, the first light emitting cell 200 may be to emit first light in the first pixel area PX1. For example, the first light emitting cell 200 may be to emit the first light to the outside of the display device DD in the first pixel area PX1.

In one or more embodiments, the first light may be red light. However, embodiments of the present disclosure are not limited thereto, and in one or more embodiments, the first light may have a wavelength different from a wavelength of the red light. For example, the first light may be green light.

The first light emitting cell 200 may include a 1-1 semiconductor layer 210, a first active layer 220, and/or a 1-2 semiconductor layer 230. For example, the first active layer 220 may be arranged (or provided) on the 1-1 semiconductor layer 210. In addition, the 1-2 semiconductor layer 230 may be arranged (or provided) on the first active layer 220.

In one or more embodiments, the 1-1 semiconductor layer 210 may include a negative-type (n-type or n-kind) semiconductor layer. For example, the 1-1 semiconductor layer 210 may include a semiconductor material, such as gallium nitride (GaN), indium aluminum gallium nitride (InAlGaN), aluminum gallium nitride (AlGaN), indium gallium nitride (InGaN), aluminum nitride (AlN), indium nitride (InN), and/or the like, and may include an n-type semiconductor layer doped with a first conductive (e.g., electrically conductive) dopant (e.g., an n-type dopant), such as silicon (Si), tin (Sn), tellurium (Te), selenium (Se), sulfur (S), oxygen (O), titanium (Ti), germanium (Ge), and/or the like. For example, the 1-1 semiconductor layer 210 may include a GaN semiconductor material doped with the first conductive (e.g., electrically conductive) dopant. However, embodiments of the present disclosure are not limited thereto, and in one or more embodiments, the 1-1 semiconductor layer 210 may include a positive-type (p-type or p-kind) semiconductor layer.

For example, the first active layer 220 may include a single well structure, a multi-well structure, a single quantum well structure, a multi-quantum well structure, a quantum dot structure, and/or a quantum line structure. For example, the first active layer 220 may include a multi-quantum well structure. In one or more embodiments, the first active layer 220 may include a structure in which a well layer and a barrier layer are alternately stacked. The well layer may include InGaN, and the barrier layer may include GaN and/or AlGaN, but embodiments of the present disclosure are not limited thereto.

In one or more embodiments, the 1-2 semiconductor layer 230 may include a p-type semiconductor layer. For example, the 1-2 semiconductor layer 230 may include a semiconductor material, such as GaN, InAlGaN, AlGaN, InGaN, AlN, InN, and/or the like, and may include a p-type semiconductor layer doped with a second conductive (e.g., electrically conductive) dopant (e.g., a p-type dopant), such as zinc (Zn), iron (Fe), magnesium (Mg), beryllium (Be), cadmium (Cd), silver (Ag), carbon (C), mercury (Hg), lithium (Li), calcium (Ca), and/or the like. For example, the 1-2 semiconductor layer 230 may include a GaN semiconductor material doped with the second conductive (e.g., electrically conductive) dopant. However, embodiments of the present disclosure are not limited thereto, and in one or more embodiments, the 1-2 semiconductor layer 230 may include an n-type semiconductor layer.

In one or more embodiments, the first light emitting cell 200 may have a trapezoidal shape (e.g., a substantially trapezoidal shape) in a cross-sectional view. However, embodiments of the present disclosure are not limited thereto, and the first light emitting cell 200 may have a shape different from the trapezoidal shape (e.g., a substantially trapezoidal shape) in the cross-sectional view. For example, the first light emitting cell 200 may have a triangular shape (e.g., a substantially triangular shape) in the cross-sectional view.

In one or more embodiments, the first lower metal layer LE1 may be arranged (or provided) under the first light emitting cell 200. For example, the first lower metal layer LE1 may be arranged (or provided) under the 1-1 semiconductor layer 210. The first lower metal layer LE1 may be arranged (or provided) in the first pixel area PX1.

For example, the first lower metal layer LE1 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the first lower metal layer LE1 may include indium tin oxide (ITO), indium zinc oxide (IZO), indium gallium oxide (IGO), and/or the like. These materials may be used alone or in (e.g., any suitable) combination with each other.

However, embodiments of the present disclosure are not limited thereto, and in one or more embodiments, the first lower metal layer LE1 may not be provided. In one or more embodiments, the 1-1 semiconductor layer 210 may be in direct contact with the first adhesive layer BM1.

In one or more embodiments, the first adhesive layer BM1 may be arranged (or provided) under the first lower metal layer LE1. The first light emitting cell 200 may be attached to the circuit board 100 through the first adhesive layer BM1. For example, the first lower metal layer LE1 may be attached to the circuit board 100 through the first adhesive layer BM1. For example, the first adhesive layer BM1 may include a solder bump, a solder ball, an anisotropic conductive (e.g., electrically conductive) film, an anisotropic conductive (e.g., electrically conductive) paste, and/or the like.

However, embodiments of the present disclosure are not limited thereto, and in one or more embodiments, the first light emitting cell 200 may be attached to the circuit board 100 by a metal bonding method. For example, the first lower metal layer LE1 may be attached to the circuit board 100 by a metal bonding method. In one or more embodiments, a first metal layer may be additionally arranged (or provided) between the circuit board 100 and the first adhesive layer BM1.

For example, each of the first adhesive layer BM1 and the first metal layer may include copper (Cu), titanium (Ti), and/or the like, and the first lower metal layer LE1 may be attached to the circuit board 100 by a Cu—Cu bonding method and/or a Ti—Ti bonding method.

In one or more embodiments, the first upper metal layer UI may be arranged (or provided) on the first light emitting cell 200. For example, the first upper metal layer UI may be arranged (or provided) on the 1-2 semiconductor layer 230. The first upper metal layer UI may be arranged (or provided) in the first pixel area PX1.

For example, the first upper metal layer UI may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the first upper metal layer UI may include ITO, IZO, IGO, and/or the like. These materials may be used alone or in (e.g., any suitable) combination with each other.

The second light emitting cell 300 may be arranged (or provided) on the first light emitting cell 200. For example, the second light emitting cell 300 may be spaced and/or apart (e.g., spaced apart or separated) from the first light emitting cell 200 in the third direction DR3. The second light emitting cell 300 may be arranged (or provided) in the first pixel area PX1. For example, the second light emitting cell 300 may be to emit second light in the first pixel area PX1. For example, the second light emitting cell 300 may be to emit the second light to the outside of the display device DD in the first pixel area PX1.

In one or more embodiments, the second light may have a wavelength different from a wavelength of the first light emitted from the first light emitting cell 200. For example, the second light may be blue light. However, embodiments of the present disclosure are not limited thereto, and in one or more embodiments, the second light may have a wavelength different from a wavelength of the blue light. For example, the second light may be green light.

The second light emitting cell 300 may include a 2-1 semiconductor layer 310, a second active layer 320, and/or a 2-2 semiconductor layer 330. For example, the second active layer 320 may be arranged (or provided) on the 2-1 semiconductor layer 310. In addition, the 2-2 semiconductor layer 330 may be arranged (or provided) on the second active layer 320.

In one or more embodiments, the 2-1 semiconductor layer 310 may include a p-type semiconductor layer. For example, the 2-1 semiconductor layer 310 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 2-1 semiconductor layer 310 may include a GaN semiconductor material doped with the second conductive (e.g., electrically conductive) dopant. However, embodiments of the present disclosure are not limited thereto, and in one or more embodiments, the 2-1 semiconductor layer 310 may include an n-type semiconductor layer.

For example, the second active layer 320 may include a single well structure, a multi-well structure, a single quantum well structure, a multi-quantum well structure, a quantum dot structure, and/or a quantum line structure. For example, the second active layer 320 may include a multi-quantum well structure. In one or more embodiments, the second active layer 320 may include a structure in which a well layer and a barrier layer are alternately stacked. The well layer may include InGaN, and the barrier layer may include GaN and/or AlGaN, but embodiments of the present disclosure are not limited thereto.

In one or more embodiments, the 2-2 semiconductor layer 330 may include an n-type semiconductor layer. For example, the 2-2 semiconductor layer 330 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the 2-2 semiconductor layer 330 may include a GaN semiconductor material doped with the first conductive (e.g., electrically conductive) dopant. However, embodiments of the present disclosure are not limited thereto, and in one or more embodiments, the 2-2 semiconductor layer 330 may include a p-type semiconductor layer.

In one or more embodiments, the second light emitting cell 300 may have a shape protruding from the second upper metal layer UE2 toward the circuit board 100. For example, the second light emitting cell 300 may have a shape in which a rectangle (e.g., a substantially rectangle) and a triangle (e.g., a substantially triangle) are sequentially stacked in a direction opposite to the third direction DR3 in the cross-sectional view. However, embodiments of the present disclosure are not limited thereto, and the shape of the second light emitting cell 300 may be suitably changed or modified.

In one or more embodiments, the second upper metal layer UE2 may be arranged (or provided) on the second light emitting cell 300. For example, the second upper metal layer UE2 may be arranged (or provided) on the 2-2 semiconductor layer 330. The second upper metal layer UE2 may be arranged (or provided) in the first pixel area PX1.

For example, the second upper metal layer UE2 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the second upper metal layer UE2 may include ITO, IZO, IGO, and/or the like. These materials may be used alone or in (e.g., any suitable) combination with each other.

The third light emitting cell 400 may be arranged (or provided) in the second pixel area PX2. For example, the third light emitting cell 400 may be spaced and/or apart (e.g., spaced apart or separated) from the second light emitting cell 300 in the first direction DR1. For example, the third light emitting cell 400 may be to emit third light from the second pixel area PX2. For example, the third light emitting cell 400 may be to emit the third light from the second pixel area PX2 to the outside of the display device DD.

In one or more embodiments, the third light may have a wavelength different from each of the wavelength of the first light emitted from the first light emitting cell 200 and the wavelength of the second light emitted from the second light emitting cell 300. For example, the third light may be green light. However, embodiments of the present disclosure are not limited thereto, and in one or more embodiments, the third light may have a wavelength different from a wavelength of the green light. For example, the third light may be blue light.

The third light emitting cell 400 may include a 3-1 semiconductor layer 410, a third active layer 420, and/or a 3-2 semiconductor layer 430. For example, the third active layer 420 may be arranged (or provided) on the 3-1 semiconductor layer 410. In addition, the 3-2 semiconductor layer 430 may be arranged (or provided) on the third active layer 420.

In one or more embodiments, the 3-1 semiconductor layer 410 may include a p-type semiconductor layer. For example, the 3-1 semiconductor layer 410 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 3-1 semiconductor layer 410 may include a GaN semiconductor material doped with the second conductive (e.g., electrically conductive) dopant. However, embodiments of the present disclosure are not limited thereto, and in one or more embodiments, the 3-1 semiconductor layer 410 may include an n-type semiconductor layer.

For example, the third active layer 420 may include a single well structure, a multi-well structure, a single quantum well structure, a multi-quantum well structure, a quantum dot structure, and/or a quantum line structure. For example, the third active layer 420 may include a multi-quantum well structure. In one or more embodiments, the third active layer 420 may include a structure in which a well layer and a barrier layer are alternately stacked. The well layer may include InGaN, and the barrier layer may include GaN and/or AlGaN, but embodiments of the present disclosure are not limited thereto.

In one or more embodiments, the 3-2 semiconductor layer 430 may include an n-type semiconductor layer. For example, the 3-2 semiconductor layer 430 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the 3-2 semiconductor layer 430 may include a GaN semiconductor material doped with the first conductive (e.g., electrically conductive) dopant. However, embodiments of the present disclosure are not limited thereto, and in one or more embodiments, the 3-2 semiconductor layer 430 may include a p-type semiconductor layer.

In one or more embodiments, the third light emitting cell 400 may have a shape in which a rectangle (e.g., a substantially rectangle) and a trapezoid (e.g., a substantially trapezoid) are sequentially stacked in a direction opposite to the third direction DR3 in the cross-sectional view. However, embodiments of the present disclosure are not limited thereto, and the shape of the third light emitting cell 400 may be suitably changed or modified.

In one or more embodiments, the third upper metal layer UE3 may be arranged (or provided) on the third light emitting cell 400. For example, the third upper metal layer UE3 may be arranged (or provided) on the 3-2 semiconductor layer 430. The third upper metal layer UE3 may be arranged (or provided) in the second pixel area PX2.

For example, the third upper metal layer UE3 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the third upper metal layer UE3 may include ITO, IZO, IGO, and/or the like. These materials may be used alone or in (e.g., any suitable) combination with each other.

The fourth light emitting cell 500 may be arranged (or provided) on the circuit board 100. The fourth light emitting cell 500 may be arranged (or provided) under the third light emitting cell 400. For example, the fourth light emitting cell 500 may be spaced and/or apart (e.g., spaced apart or separated) from the third light emitting cell 400 in the direction opposite to the third direction DR3. The fourth light emitting cell 500 may be arranged (or provided) in the second pixel area PX2. For example, the fourth light emitting cell 500 may be to emit the fourth light from the second pixel area PX2. For example, the fourth light emitting cell 500 may be to emit the fourth light from the second pixel area PX2 to the outside of the display device DD.

In one or more embodiments, the fourth light may be red light. For example, the fourth light and the first light emitted from the first light emitting cell 200 may have substantially the same wavelength. For example, the fourth light emitting cell 500 may be to emit the first light. However, embodiments of the present disclosure are not limited thereto, and in one or more embodiments, the fourth light may have a wavelength different from a wavelength of the red light. For example, the fourth light may be green light.

The fourth light emitting cell 500 may include a 4-1 semiconductor layer 510, a fourth active layer 520, and/or a 4-2 semiconductor layer 530. For example, the fourth active layer 520 may be arranged (or provided) on the 4-1 semiconductor layer 510. Also, the 4-2 semiconductor layer 530 may be arranged (or provided) on the fourth active layer 520.

In one or more embodiments, the 4-1 semiconductor layer 510 may include an n-type semiconductor layer. For example, the 4-1 semiconductor layer 510 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the 4-1 semiconductor layer 510 may include a GaN semiconductor material doped with the first conductive (e.g., electrically conductive) dopant. However, embodiments of the present disclosure are not limited thereto, and in one or more embodiments, the 4-1 semiconductor layer 510 may include a p-type semiconductor layer.

For example, the fourth active layer 520 may include a single well structure, a multi-well structure, a single quantum well structure, a multi-quantum well structure, a quantum dot structure, and/or a quantum line structure. For example, the fourth active layer 520 may include a multi-quantum well structure. In one or more embodiments, the fourth active layer 520 may include a structure in which a well layer and a barrier layer are alternately stacked. The well layer may include InGaN, and the barrier layer may include GaN and/or AlGaN, but embodiments of the present disclosure are not limited thereto.

In one or more embodiments, the 4-2 semiconductor layer 530 may include a p-type semiconductor layer. For example, the 4-2 semiconductor layer 530 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 4-2 semiconductor layer 530 may include a GaN semiconductor material doped with the second conductive (e.g., electrically conductive) dopant. However, embodiments of the present disclosure are not limited thereto, and in one or more embodiments, the 4-2 semiconductor layer 530 may include an n-type semiconductor layer.

In one or more embodiments, the fourth light emitting cell 500 may have a trapezoidal shape (e.g., a substantially trapezoidal shape) in the cross-sectional view. However, embodiments of the present disclosure are not limited thereto, and the fourth light emitting cell 500 may have a shape different from the trapezoidal shape (e.g., a substantially trapezoidal shape) in the cross-sectional view. For example, the fourth light emitting cell 500 may have a triangular shape (e.g., a substantially triangular shape) in the cross-sectional view.

In one or more embodiments, the second lower metal layer LE2 may be arranged (or provided) under the fourth light emitting cell 500. For example, the second lower metal layer LE2 may be arranged (or provided) under the 4-1 semiconductor layer 510. The second lower metal layer LE2 may be arranged (or provided) in the second pixel area PX2.

For example, the second lower metal layer LE2 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the second lower metal layer LE2 may include ITO, IZO, IGO, and/or the like. These materials may be used alone or in (e.g., any suitable) combination with each other.

However, embodiments of the present disclosure are not limited thereto, and in one or more embodiments, the second lower metal layer LE2 may not be provided. In one or more embodiments, the 4-1 semiconductor layer 510 may be in direct contact with the second adhesive layer BM2.

In one or more embodiments, the second adhesive layer BM2 may be arranged (or provided) under the second lower metal layer LE2. The fourth light emitting cell 500 may be attached to the circuit board 100 through the second adhesive layer BM2. For example, the second lower metal layer LE2 may be attached to the circuit board 100 through the second adhesive layer BM2. For example, the second adhesive layer BM2 may include a solder bump, a solder ball, an anisotropic conductive (e.g., electrically conductive) film, an anisotropic conductive (e.g., electrically conductive) paste, and/or the like.

However, embodiments of the present disclosure are not limited thereto, and in one or more embodiments, the fourth light emitting cell 500 may be attached to the circuit board 100 by a metal bonding method. For example, the second lower metal layer LE2 may be attached to the circuit board 100 by a metal bonding method. In one or more embodiments, a second metal layer may be additionally arranged (or provided) between the circuit board 100 and the second adhesive layer BM2.

For example, each of the second adhesive layer BM2 and the second metal layer may include copper (Cu), titanium (Ti), and/or the like, and the second lower metal layer LE2 may be attached to the circuit board 100 by a Cu—Cu bonding method and/or a Ti—Ti bonding method.

In one or more embodiments, the fourth upper metal layer UE4 may be arranged (or provided) on the fourth light emitting cell 500. For example, the fourth upper metal layer UE4 may be arranged (or provided) on the 4-2 semiconductor layer 530. The fourth upper metal layer UE4 may be arranged (or provided) in the second pixel area PX2.

For example, the fourth upper metal layer UE4 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the fourth upper metal layer UE4 may include ITO, IZO, IGO, and/or the like. These materials may be used alone or in (e.g., any suitable) combination with each other.

The first insulating layer IL1 may be arranged (or provided) on the circuit board 100. For example, the first insulating layer IL1 may include silicon oxide (SiOₓ″, silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

The first conductive layer CL1 may be arranged (or provided) on the first insulating layer IL1, the first light emitting cell 200, and/or the fourth light emitting cell 500. The first conductive layer CL1 may be in contact with the first upper metal layer UE1. For example, the first conductive layer CL1 may be electrically connected to (or coupled to) the first upper metal layer UE1. The first conductive layer CL1 may be in contact with the fourth upper metal layer UE4. For example, the first conductive layer CL1 may be electrically connected to (or coupled to) the fourth upper metal layer UE4.

For example, the first conductive layer CL1 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the first conductive layer CL1 may include ITO, IZO, IGO, and/or the like. These materials may be used alone or in (e.g., any suitable) combination with each other.

The second insulating layer IL2 may be arranged (or provided) on the first conductive layer CL1. For example, the second insulating layer IL2 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

The first side insulating layer SL1 may be arranged (or provided) on the circuit board 100. The first side insulating layer SL1 may cover a 1-1 connection electrode CE1-1 to be described in more detail later. For example, the first side insulating layer SL1 may cover a side surface of the 1-1 connection electrode CE1-1. The first side insulating layer SL1 may be connected to (or coupled to) the second insulating layer IL2 and extend in the third direction DR3. The first side insulating layer SL1 and the second insulating layer IL2 may include substantially the same material.

The second side insulating layer SL2 may be arranged (or provided) on the circuit board 100. The second side insulating layer SL2 may cover a 2-2 connection electrode CE2-2 to be described in more detail later. For example, the second side insulating layer SL2 may cover a side surface of the 2-2 connection electrode CE2-2. The second side insulating layer SL2 may be connected to (or coupled to) the second insulating layer IL2 and may extend in the third direction DR3. The second side insulating layer SL2 and the second insulating layer IL2 may include substantially the same material.

The second conductive layer CL2 may be arranged (or provided) on the second insulating layer IL2. For example, the second conductive layer CL2 may be in contact with the fourth connection electrode CE4 to be described in more detail later. For example, the second conductive layer CL2 may be electrically connected to (or coupled to) the fourth connection electrode CE4.

For example, the second conductive layer CL2 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the second conductive layer CL2 may include ITO, IZO, IGO, and/or the like. These materials may be used alone or in (e.g., any suitable) combination with each other.

The third conductive layer CL3 may be arranged (or provided) on the second conductive layer CL2. For example, the third conductive layer CL3 may be in contact with the second conductive layer CL2. For example, the third conductive layer CL3 may be electrically connected to (or coupled to) the second conductive layer CL2.

For example, the third conductive layer CL3 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the third conductive layer CL3 may include ITO, IZO, IGO, and/or the like. These materials may be used alone or in (e.g., any suitable) combination with each other.

The third insulating layer IL3 may be arranged (or provided) on the third conductive layer CL3. For example, the third insulating layer IL3 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

The fourth conductive layer CL4 may be arranged (or provided) on the third insulating layer IL3. For example, the fourth conductive layer CL4 may cover the second light emitting cell 300 and/or the third light emitting cell 400. For example, the fourth conductive layer CL4 may cover the 2-1 semiconductor layer 310 and/or the 3-1 semiconductor layer 410. The fourth conductive layer CL4 may be in contact with the fifth connection electrode CE5 to be described in more detail later. For example, the fourth conductive layer CL4 may be electrically connected to (or coupled to) the fifth connection electrode CE5. The fourth conductive layer CL4 may be in contact with the sixth connection electrode CE6 to be described in more detail later. For example, the fourth conductive layer CL4 may be electrically connected to (or coupled to) the sixth connection electrode CE6.

The fourth insulating layer IL4 may be arranged (or provided) on the fourth conductive layer CL4. The fourth insulating layer IL4 may define a first cutout portion in a portion at least partially overlapping the first pixel area PX1 in the plan view. The 2-2 semiconductor layer 330 may be arranged (or provided) in the first cutout portion. The fourth insulating layer IL4 may be in contact with one end of each of the 2-1 semiconductor layer 310 and the second active layer 320.

The fourth insulating layer IL4 may define a second cutout portion in a portion at least partially overlapping the second pixel area PX2 in the plan view. The 3-2 semiconductor layer 430 may be arranged (or provided) in the second cutout portion. The fourth insulating layer IL4 may be in contact with one end of each of the 3-1 semiconductor layer 410 and the third active layer 420.

For example, the fourth insulating layer IL4 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

The fifth insulating layer IL5 may be arranged (or provided) on the fourth insulating layer IL4. For example, the fifth insulating layer IL5 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

The second side insulating layer SL2 may cover a 1-2 connection electrode CE1-2 to be described in more detail later. For example, the second side insulating layer SL2 may cover a side surface of the 1-2 connection electrode CE1-2.

For example, the second side insulating layer SL2 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

The third side insulating layer SL3 may cover a 2-1 connection electrode CE2-1 to be described in more detail later. For example, the third side insulating layer SL3 may cover a side surface of the 2-1 connection electrode CE2-1.

For example, the third side insulating layer SL3 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

The sixth insulating layer IL6 may be arranged (or provided) on the fifth insulating layer IL5. For example, the sixth insulating layer IL6 may cover the second upper metal layer UE2 and/or the third upper metal layer UE3.

For example, the sixth insulating layer IL6 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

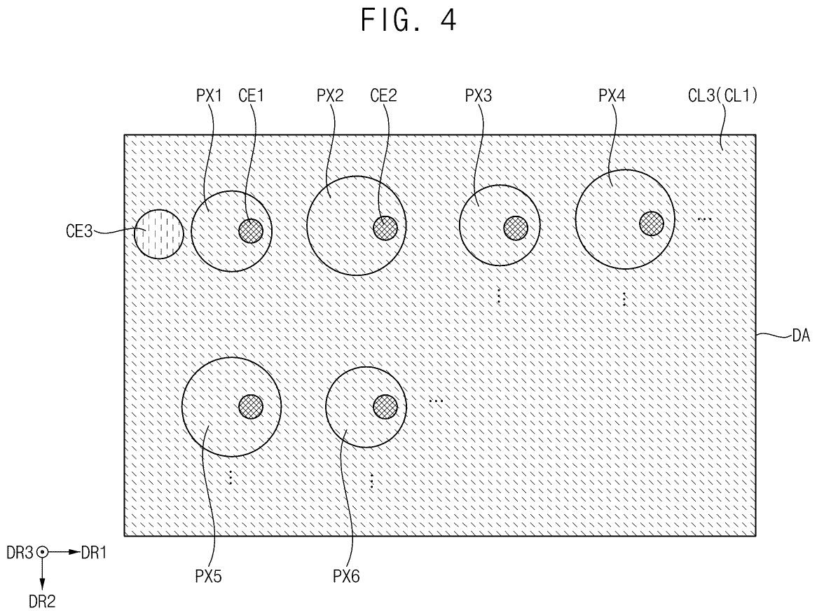

FIG. 4 is a plan view illustrating a display area included in the display device of FIG. 1. For example, FIG. 4 is a plan view illustrating an example of arrangements or positions of the first connection electrode CE1, the second connection electrode CE2, and the third connection electrode CE3 of FIG. 3.

Referring further to FIG. 4, the first connection electrode CE1 may penetrate at least a portion of each of the first light emitting cell 200 and the second light emitting cell 300. For example, the first connection electrode CE1 may include a 1-1 connection electrode CE1-1 penetrating at least a portion of the first light emitting cell 200 and/or a 1-2 connection electrode CE1-2 penetrating at least a portion of the second light emitting cell 300.

The 1-1 connection electrode CE1-1 may be electrically connected to (or coupled to) the third electrode 130 through a first opening OP1 formed (or provided) in a first side insulating layer SL1. The 1-1 connection electrode CE1-1 and the 1-2 connection electrode CE1-2 may be electrically connected to (or coupled to) each other through a second opening OP2 formed (or provided) in the second side insulating layer SL2. The 1-2 connection electrode CE1-2 may be electrically connected to (or coupled to) the second upper metal layer UE2. The second upper metal layer UE2 may be electrically connected to (or coupled to) the 2-2 semiconductor layer 330. For example, the 2-2 semiconductor layer 330 may be electrically connected to (or coupled to) the third electrode 130 through the first connection electrode CE1 and/or the second upper metal layer UE2. For example, the third electrode 130 may be a cathode of the second light emitting cell 300.

For example, the first connection electrode CE1 may include a metal, a metal nitride, a conductive (e.g., electrically conductive) metal oxide, a transparent conductive (e.g., electrically conductive) material, and/or the like. For example, the first connection electrode CE1 may include molybdenum, aluminum, chromium, titanium, gold, nickel, neodymium, copper, and/or the like. These materials may be used alone or in (e.g., any suitable) combination with each other.

The second connection electrode CE2 may penetrate at least a portion of each of the third light emitting cell 400 and the fourth light emitting cell 500. For example, the second connection electrode CE2 may include a 2-1 connection electrode CE2-1 penetrating at least a portion of the third light emitting cell 400 and/or a 2-2 connection electrode CE2-2 penetrating at least a portion of the fourth light emitting cell 500.

The 2-2 connection electrode CE2-2 may be electrically connected to (or coupled to) the fifth electrode 150 through a fourth opening OP4 formed (or provided) in the fourth side insulating layer SL4. The 2-2 connection electrode CE2-2 and the 2-1 connection electrode CE2-1 may be electrically connected to (or coupled to) each other through a third opening OP3 formed (or provided) in the third side insulating layer SL3. The 2-1 connection electrode CE2-1 may be electrically connected to (or coupled to) the third upper metal layer UE3. The third upper metal layer UE3 may be electrically connected to (or coupled to) the 3-2 semiconductor layer 430. For example, the 3-2 semiconductor layer 430 may be electrically connected to (or coupled to) the fifth electrode 150 through the second connection electrode CE2 and/or the third upper metal layer UE3. For example, the fifth electrode 150 may be a cathode of the third light emitting cell 400.

For example, the second connection electrode CE2 may include a metal, a metal nitride, a conductive (e.g., electrically conductive) metal oxide, a transparent conductive (e.g., electrically conductive) material, and/or the like. For example, the second connection electrode CE2 may include molybdenum, aluminum, chromium, titanium, gold, nickel, neodymium, copper, and/or the like. These materials may be used alone or in (e.g., any suitable) combination with each other.

The 1-1 semiconductor layer 210 may be electrically connected to (or coupled to) the second electrode 120. For example, the 1-1 semiconductor layer 210 may be electrically connected to (or coupled to) the second electrode 120 through the first lower metal layer LE1 and/or the first adhesive layer BM1. For example, the second electrode 120 may be a cathode electrode of the first light emitting cell 200.

The 4-1 semiconductor layer 510 may be electrically connected to (or coupled to) the fourth electrode 140. For example, the 4-1 semiconductor layer 510 may be electrically connected to (or coupled to) the fourth electrode 140 through the second lower metal layer LE2 and/or the second adhesive layer BM2. For example, the fourth electrode 140 may be a cathode electrode of the fourth light emitting cell 500.

The third connection electrode CE3 may be arranged (or provided) on the circuit board 100. For example, the third connection electrode CE3 may be arranged (or provided) between the circuit board 100 and the first conductive layer CL1. The third connection electrode CE3 may be spaced and/or apart (e.g., spaced apart or separated) from the first pixel area PX1 in a direction opposite to the first direction DR1. For example, the third connection electrode CE3 may be spaced and/or apart (e.g., spaced apart or separated) from the first light emitting cell 200 in the direction opposite to the first direction DR1. For example, the third connection electrode CE3 may be arranged (or provided) at one side of the display area DA. However, embodiments of the present disclosure are not limited thereto, and an arrangement or position of the third connection electrode CE3 in the plan view may be suitably changed or modified. For example, the third connection electrode CE3 may at least partially overlap the non-display area NDA in the plan view.

For example, the third connection electrode CE3 may include a metal, a metal nitride, a conductive (e.g., electrically conductive) metal oxide, a transparent conductive (e.g., electrically conductive) material, and/or the like. For example, the third connection electrode CE3 may include molybdenum, aluminum, chromium, titanium, gold, nickel, neodymium, copper, and/or the like. These materials may be used alone or in (e.g., any suitable) combination with each other.

The fourth connection electrode CE4 may be arranged (or provided) between the first conductive layer CL1 and the second conductive layer CL2. The fourth connection electrode CE4 may at least partially overlap the third connection electrode CE3 in the plan view.

For example, the fourth connection electrode CE4 may include a metal, a metal nitride, a conductive (e.g., electrically conductive) metal oxide, a transparent conductive (e.g., electrically conductive) material, and/or the like. For example, the fourth connection electrode CE4 may include molybdenum, aluminum, chromium, titanium, gold, nickel, neodymium, copper, and/or the like. These materials may be used alone or in (e.g., any suitable) combination with each other.

The fifth connection electrode CE5 may be arranged (or provided) on the third conductive layer CL3. For example, the fifth connection electrode CE5 may be arranged (or provided) between the third conductive layer CL3 and the fourth conductive layer CL4. For example, the fifth connection electrode CE5 may at least partially overlap the third connection electrode CE3 in the plan view.

For example, the fifth connection electrode CE5 may include a metal, a metal nitride, a conductive (e.g., electrically conductive) metal oxide, a transparent conductive (e.g., electrically conductive) material, and/or the like. For example, the fifth connection electrode CE5 may include molybdenum, aluminum, chromium, titanium, gold, nickel, neodymium, copper, and/or the like. These materials may be used alone or in (e.g., any suitable) combination with each other.

The sixth connection electrode CE6 may be arranged (or provided) on the third conductive layer CL3. For example, the sixth connection electrode CE6 may be arranged (or provided) between the third conductive layer CL3 and the fourth conductive layer CL4. For example, the sixth connection electrode CE6 may be spaced and/or apart (e.g., spaced apart or separated) from the fifth connection electrode CE5 in the first direction DR1. For example, the sixth connection electrode CE6 may be arranged (or provided) between the first pixel area PX1 and the second pixel area PX2.

For example, the sixth connection electrode CE6 may include a metal, a metal nitride, a conductive (e.g., electrically conductive) metal oxide, a transparent conductive (e.g., electrically conductive) material, and/or the like. For example, the sixth connection electrode CE6 may include molybdenum, aluminum, chromium, titanium, gold, nickel, neodymium, copper, and/or the like. These materials may be used alone or in (e.g., any suitable) combination with each other.

The seventh connection electrode CE7 may be arranged (or provided) on the circuit board 100. For example, the seventh connection electrode CE7 may be arranged (or provided) between the circuit board 100 and the first conductive layer CL1. For example, the seventh connection electrode CE7 may be spaced and/or apart (e.g., spaced apart or separated) from the third connection electrode CE3 in the first direction DR1. For example, the seventh connection electrode CE7 may be arranged (or provided) between the first pixel area PX1 and the second pixel area PX2. The seventh connection electrode CE7 may prevent or reduce color mixing (or a degree or occurrence of color mixing may be reduced) between the first light emitting cell 200 and the fourth light emitting cell 500. In addition, an electrical signal may be well applied from the first electrode 110 to the 4-2 semiconductor layer 530 through the seventh connection electrode CE7. The seventh connection electrode CE7 may not be provided.

For example, the seventh connection electrode CE7 may include a metal, a metal nitride, a conductive (e.g., electrically conductive) metal oxide, a transparent conductive (e.g., electrically conductive) material, and/or the like. For example, the seventh connection electrode CE7 may include molybdenum, aluminum, chromium, titanium, gold, nickel, neodymium, copper, and/or the like. These materials may be used alone or in (e.g., any suitable) combination with each other.

In one or more embodiments, the first electrode 110 may be electrically connected to (or coupled to) the third connection electrode CE3. The third connection electrode CE3 may be electrically connected to (or coupled to) the first conductive layer CL1. The first conductive layer CL1 may be electrically connected to (or coupled to) the first upper metal layer UE1. The first conductive layer CL1 may be electrically connected to (or coupled to) the seventh connection electrode CE7. The first conductive layer CL1 may be electrically connected to (or coupled to) the fourth upper metal layer UE4. The first conductive layer CL1 may be electrically connected to (or coupled to) the fourth connection electrode CE4. The fourth connection electrode CE4 may be electrically connected to (or coupled to) the second conductive layer CL2. The second conductive layer CL2 may be electrically connected to (or coupled to) the third conductive layer CL3. The third conductive layer CL3 may be electrically connected to (or coupled to) the fifth connection electrode CE5. The third conductive layer CL3 may be electrically connected to (or coupled to) the sixth connection electrode CE6.

The 1-2 semiconductor layer 230 may be electrically connected to (or coupled to) the first electrode 110. For example, the 1-2 semiconductor layer 230 may be electrically connected to (or coupled to) the first electrode 110 through the third connection electrode CE3, the first conductive layer CL1, and/or the first upper metal layer UI.

The 2-1 semiconductor layer 310 may be electrically connected to (or coupled to) the first electrode 110. For example, the 2-1 semiconductor layer 310 may be electrically connected to (or coupled to) the first electrode 110 through the third connection electrode CE3, the first conductive layer CL1, the fourth connection electrode CE4, the second conductive layer CL2, the third conductive layer CL3, the fifth connection electrode CE5, and/or the fourth conductive layer CL4.

The 3-1 semiconductor layer 410 may be electrically connected to (or coupled to) the first electrode 110. For example, the 3-1 semiconductor layer 410 may be electrically connected to (or coupled to) the first electrode 110 through the third connection electrode CE3, the first conductive layer CL1, the fourth connection electrode CE4, the second conductive layer CL2, the third conductive layer CL3, the sixth connection electrode CE6, and/or the fourth conductive layer CL4.

The 4-2 semiconductor layer 530 may be electrically connected to (or coupled to) the first electrode 110. For example, the 4-2 semiconductor layer 530 may be electrically connected to (or coupled to) the first electrode 110 through the third connection electrode CE3, the first conductive layer CL1, and/or the fourth upper metal layer UE4.

In one or more embodiments, the first electrode 110 may be an anode of each of the first light emitting cell 200, the second light emitting cell 300, the third light emitting cell 400, and the fourth light emitting cell 500.

The third pixel area PX3 may be spaced and/or apart (e.g., spaced apart or separated) from the second pixel area PX2 in the first direction DR1. The third pixel area PX3 and the first pixel area PX1 may have substantially the same structure. For example, a cross-sectional structure of the third pixel area PX3 and a cross-sectional structure of the first pixel area PX1 may be substantially the same.

The fourth pixel area PX4 may be spaced and/or apart (e.g., spaced apart or separated) from the third pixel area PX3 in the first direction DR1. The fourth pixel area PX4 and the second pixel area PX2 may have substantially the same structure. For example, a cross-sectional structure of the fourth pixel area PX4 and a cross-sectional structure of a second pixel area PX2 may be substantially the same.

The fifth pixel area PX5 may be spaced and/or apart (e.g., spaced apart or separated) from the first pixel area PX1 in the second direction DR2. The fifth pixel area PX5 and the second pixel area PX2 may have substantially the same structure. For example, a cross-sectional structure of the fifth pixel area PX5 and a cross-sectional structure of the second pixel area PX2 may be substantially the same.

The sixth pixel area PX6 may be spaced and/or apart (e.g., spaced apart or separated) from the second pixel area PX2 in the second direction DR2. In addition, the sixth pixel area PX6 may be spaced and/or apart (e.g., spaced apart or separated) from the fifth pixel area PX5 in the first direction DR1. The sixth pixel area PX6 and the first pixel area PX1 may have substantially the same structure. For example, a cross-sectional structure of the sixth pixel area PX6 and a cross-sectional structure of the first pixel area PX1 may be substantially the same.

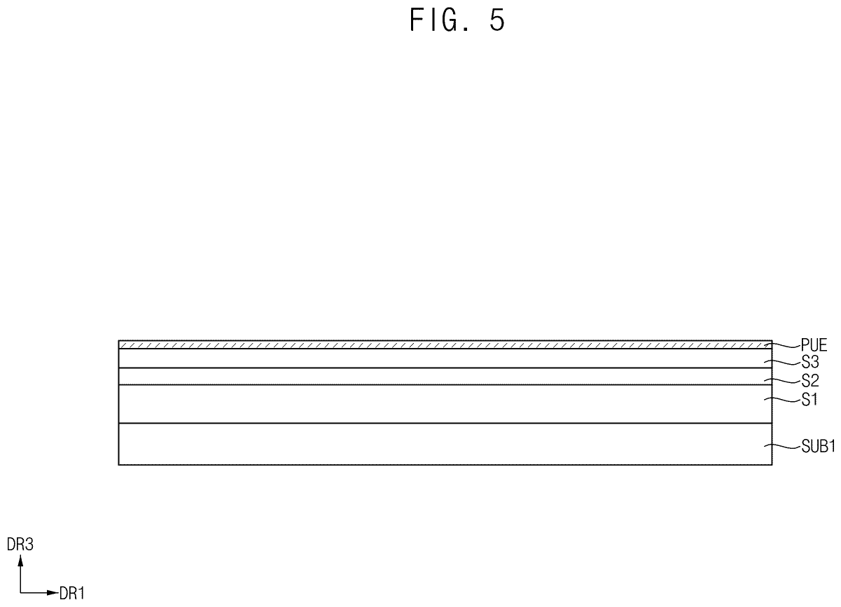

FIGS. 5, 6, 7, 8, 9, 10, 11, 12, 13, 14, 15, 16, 17, 18, 19, 20, 21, 22, 23, 24, 25, 26, 27, 28, 29, 30, 31, 32, and 33 are cross-sectional views illustrating a method of manufacturing the display device of FIG. 2.

Referring to FIG. 5, a first semiconductor layer S1 may be formed (or provided) on a first growth substrate SUB1. The first growth substrate SUB1 may be an epitaxial substrate. For example, the epitaxial substrate may include a silicon substrate, a silicon carbide substrate, a sapphire substrate, and/or the like. The first semiconductor layer S1 may be formed (or provided) by an epitaxial growth method.

In one or more embodiments, the first semiconductor layer S1 may include an n-type semiconductor layer. For example, the first semiconductor layer S1 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the first semiconductor layer S1 may include a GaN semiconductor material doped with the first conductive (e.g., electrically conductive) dopant.

An active layer S2 may be formed (or provided) on the first semiconductor layer S1. The active layer S2 may be formed (or provided) by an epitaxial growth method. For example, the active layer S2 may include a single well structure, a multi-well structure, a single quantum well structure, a multi-quantum well structure, a quantum dot structure, and/or a quantum line structure. For example, the active layer S2 may include a multi-quantum well structure. In one or more embodiments, the active layer S2 may include a structure in which a well layer and a barrier layer are alternately stacked. The well layer may include InGaN, and the barrier layer may include GaN and/or AlGaN, but embodiments of the present disclosure are not limited thereto.

A second semiconductor layer S3 may be formed (or provided) on the active layer S2. The second semiconductor layer S3 may be formed (or provided) by an epitaxial growth method. In one or more embodiments, the second semiconductor layer S3 may include a p-type semiconductor layer. For example, the second semiconductor layer S3 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the second semiconductor layer S3 may include a GaN semiconductor material doped with the second conductive (e.g., electrically conductive) dopant.

A preliminary upper metal layer PUE may be formed (or provided) on the second semiconductor layer S3. For example, the preliminary upper metal layer PUE may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the preliminary upper metal layer PUE may include ITO, IZO, IGO, and/or the like. These materials may be used alone or in (e.g., any suitable) combination with each other.

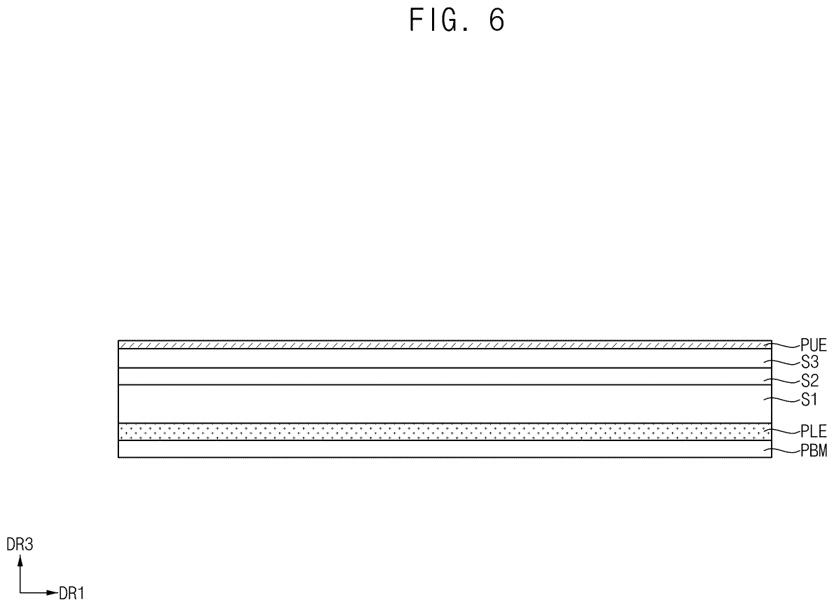

Referring to FIGS. 5 and 6, the first growth substrate SUB1 may be removed. For example, the first growth substrate SUB1 may be removed by a laser lift-off (LLO) method.

After the first growth substrate SUB1 is removed, a preliminary lower metal layer PLE may be formed (or provided) under the first semiconductor layer S1. For example, the preliminary lower metal layer PLE may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the preliminary lower metal layer PLE may include ITO, IZO, IGO, and/or the like. These materials may be used alone or in (e.g., any suitable) combination with each other.

A preliminary adhesive layer PBM may be formed (or provided) under the preliminary lower metal layer PLE. In one or more embodiments, the preliminary adhesive layer PBM may include a solder bump, a solder ball, an anisotropic conductive (e.g., electrically conductive) film, an anisotropic conductive (e.g., electrically conductive) paste, and/or the like.

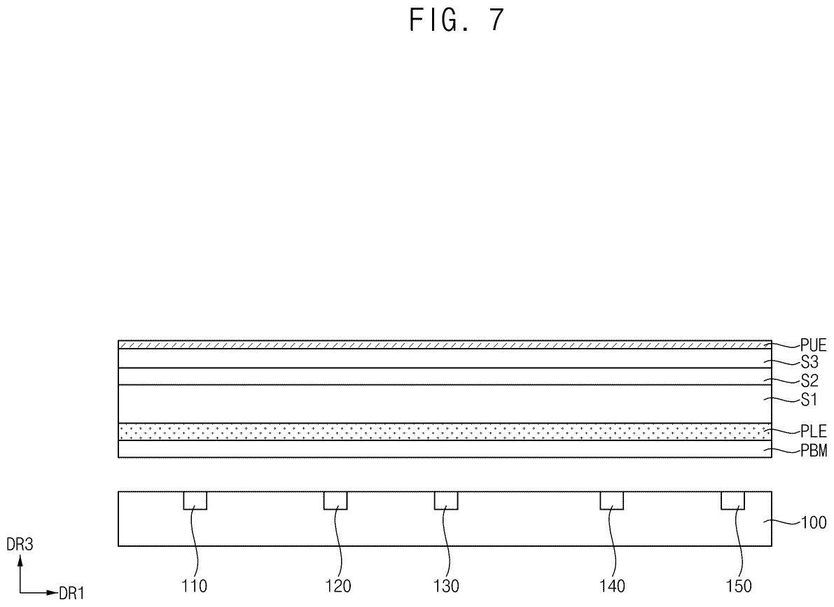

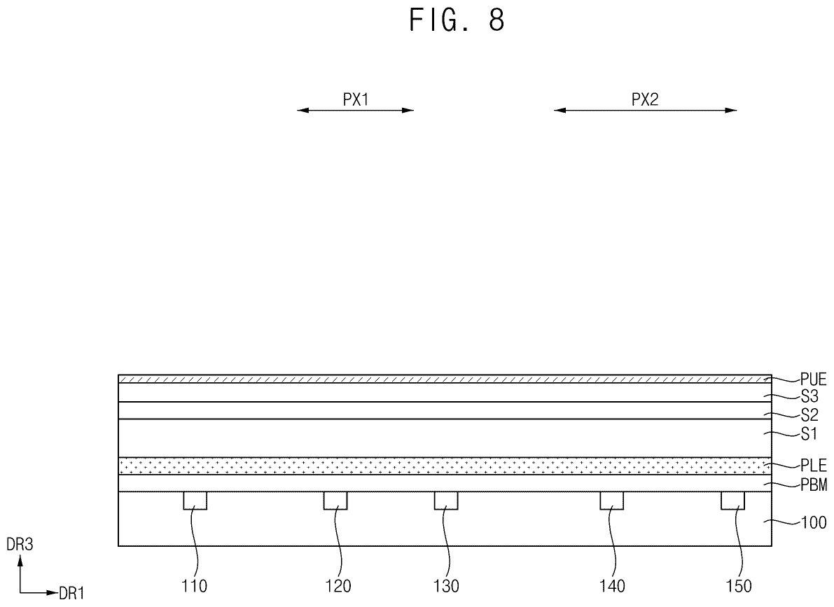

Referring to FIGS. 7 and 8, the preliminary adhesive layer PBM, the preliminary lower metal layer PLE, the first semiconductor layer S1, the active layer S2, the second semiconductor layer S3, and/or the preliminary upper metal layer PUE may be attached to the circuit board 100. For example, the preliminary lower metal layer PLE may be attached to the circuit board 100 through the preliminary adhesive layer PBM.

The circuit board 100 may be formed (or provided) to include a TFT, a PMOS, an NMOS, a CMOS structure, and/or the like. The first electrode 110, the second electrode 120, the third electrode 130, the fourth electrode 140, and/or the fifth electrode 150 may be formed (or provided) in the circuit board 100. For example, each of the first electrode 110, the second electrode 120, the third electrode 130, the fourth electrode 140, and/or the fifth electrode 150 may include a metal, an alloy, a metal nitride, a conductive (e.g., electrically conductive) metal oxide, a transparent conductive (e.g., electrically conductive) material, and/or the like. These materials may be used alone or in (e.g., any suitable) combination with each other.

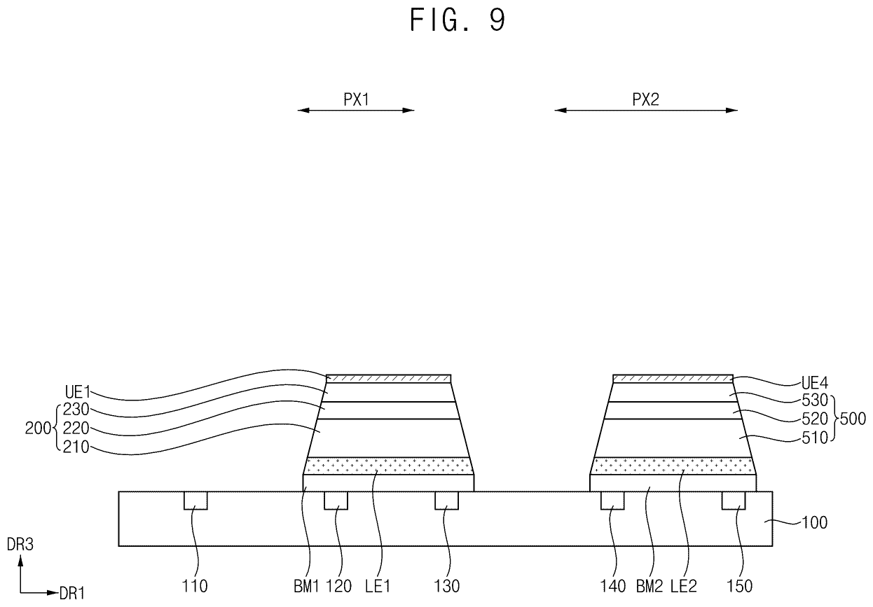

Referring to FIGS. 8 and 9, a portion of the preliminary adhesive layer PBM, the preliminary lower metal layer PLE, the first semiconductor layer S1, the active layer S2, the second semiconductor layer S3, and/or the preliminary upper metal layer PUE may be removed to form (or provide) the first light emitting cell 200 and/or the fourth light emitting cell 500. For example, a portion of the preliminary adhesive layer PBM, the preliminary lower metal layer PLE, the first semiconductor layer S1, the active layer S2, the second semiconductor layer S3, and/or the preliminary upper metal layer PUE that does not overlap the first pixel area PX1 and/or the second pixel area PX2 in the plan view may be removed to form (or provide) the first light emitting cell 200 and/or the fourth light emitting cell 500.

For example, a portion of the preliminary adhesive layer PBM that does not overlap the first pixel area PX1 and/or the second pixel area PX2 in the plan view may be removed to form (or provide) the first adhesive layer BM1 and/or the second adhesive layer BM2. The first adhesive layer BM1 may be formed (or provided) in the first pixel area PX1, and the second adhesive layer BM2 may be formed (or provided) in the second pixel area PX2.

A portion of the preliminary lower metal layer PLE that does not overlap the first pixel area PX1 and/or the second pixel area PX2 in the plan view may be removed to form (or provide) the first lower metal layer LE1 and/or the second lower metal layer LE2. The first lower metal layer LE1 may be formed (or provided) in the first pixel area PX1, and the second lower metal layer LE2 may be formed (or provided) in the second pixel area PX2.

A portion of the first semiconductor layer S1 that does not overlap the first pixel area PX1 and/or the second pixel area PX2 in the plan view may be removed to form (or provide) the 1-1 semiconductor layer 210 and/or the 4-1 semiconductor layer 510. The 1-1 semiconductor layer 210 may be formed (or provided) in the first pixel area PX1, and the 4-1 semiconductor layer 510 may be formed (or provided) in the second pixel area PX2.

A portion of the active layer S2 that does not overlap the first pixel area PX1 and/or the second pixel area PX2 in the plan view may be removed to form (or provide) the first active layer 220 and/or the fourth active layer 520. The first active layer 220 may be formed (or provided) in the first pixel area PX1, and the fourth active layer 520 may be formed (or provided) in the second pixel area PX2.

A portion of the second semiconductor layer S3 that does not overlap the first pixel area PX1 and/or the second pixel area PX2 in the plan view may be removed to form (or provide) the 1-2 semiconductor layer 230 and/or the 4-2 semiconductor layer 530. The 1-2 semiconductor layer 230 may be formed (or provided) in the first pixel area PX1, and the 4-2 semiconductor layer 530 may be formed (or provided) in the second pixel area PX2.

A portion of the preliminary upper metal layer PUE that does not overlap the first pixel area PX1 and/or the second pixel area PX2 in the plan view may be removed to form (or provide) the first upper metal layer UI and/or the second upper metal layer UE2. The first upper metal layer UI may be formed (or provided) in the first pixel area PX1, and the second upper metal layer UE2 may be formed (or provided) in the second pixel area PX2.

The first light emitting cell 200 may include the 1-1 semiconductor layer 210, the first active layer 220, and/or the 1-2 semiconductor layer 230. The fourth light emitting cell 500 may include the 4-1 semiconductor layer 510, the fourth active layer 520, and/or the 4-2 semiconductor layer 530.

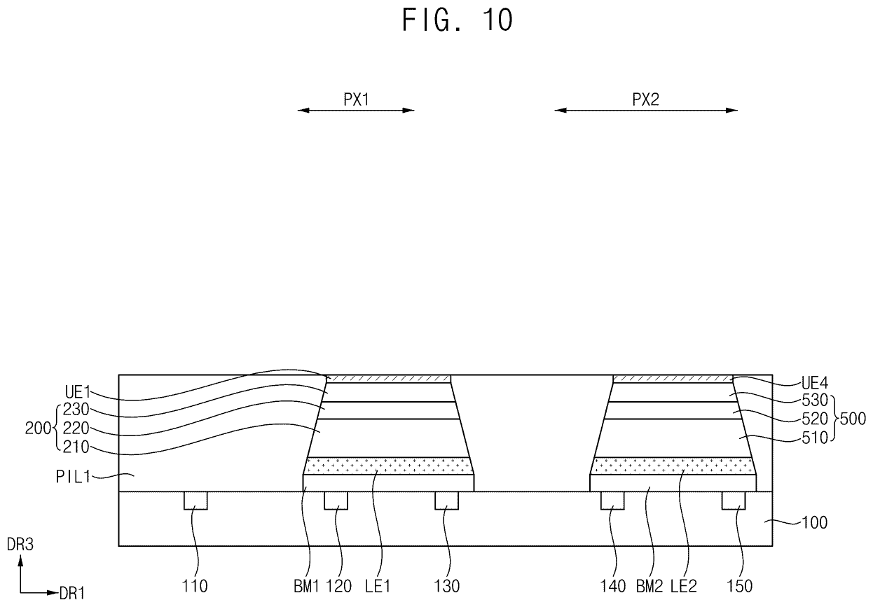

Referring to FIG. 10, a first preliminary insulating layer PIL1 may be formed (or provided) on the circuit board 100. For example, the first preliminary insulating layer PIL1 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

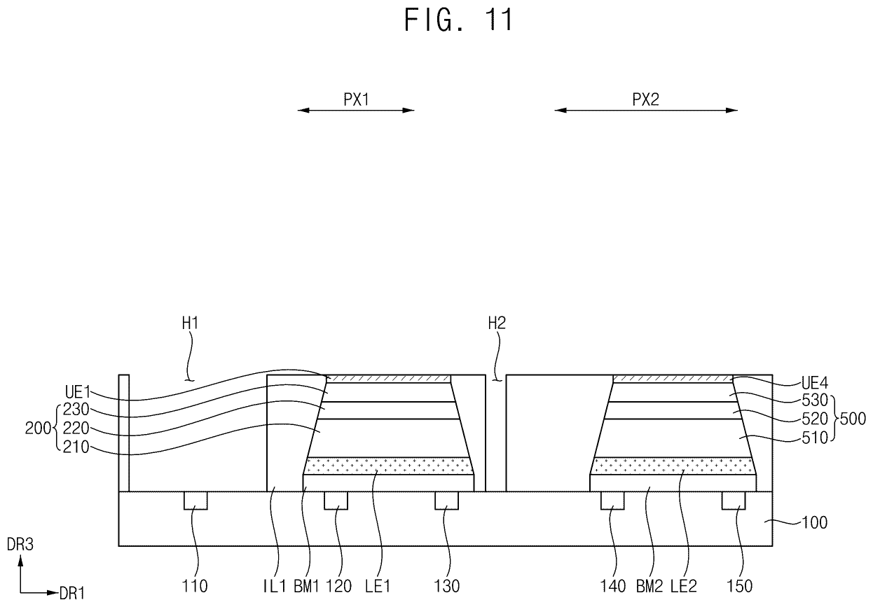

Referring to FIGS. 10 and 11, a portion of the first preliminary insulating layer PIL1 may be removed. For example, a first hole H1 and/or a second hole H2 may be formed (or provided) in the first preliminary insulating layer PIL1. In one or more embodiments, the first insulating layer IL1 may be formed (or provided). The first hole H1 may be formed (or provided) to be spaced and/or apart (e.g., spaced apart or separated) from the first pixel area PX1 in the direction opposite to the first direction DR1. The second hole H2 may be formed (or provided) between the first pixel area PX1 and the second pixel area PX2.

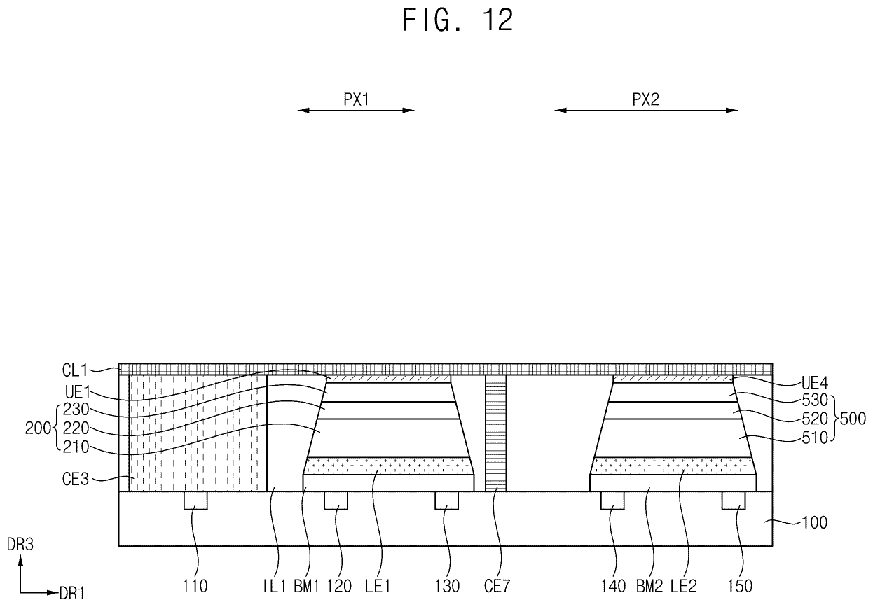

Referring to FIG. 12, the third connection electrode CE3 may be formed (or provided) in the first hole H1. For example, the third connection electrode CE3 may be formed (or provided) through a damascene process. For example, the third connection electrode CE3 may include a metal, a metal nitride, a conductive (e.g., electrically conductive) metal oxide, a transparent conductive (e.g., electrically conductive) material, and/or the like. For example, the third connection electrode CE3 may include molybdenum, aluminum, chromium, titanium, gold, nickel, neodymium, copper, and/or the like. These materials may be used alone or in (e.g., any suitable) combination with each other.

The seventh connection electrode CE7 may be formed (or provided) in the second hole H2. For example, the seventh connection electrode CE7 may be formed (or provided) through a damascene process. For example, the seventh connection electrode CE7 may include a metal, a metal nitride, a conductive (e.g., electrically conductive) metal oxide, a transparent conductive (e.g., electrically conductive) material, and/or the like. For example, the seventh connection electrode CE7 may include molybdenum, aluminum, chromium, titanium, gold, nickel, neodymium, copper, and/or the like. These materials may be used alone or in (e.g., any suitable) combination with each other.

The first conductive layer CL1 may be formed (or provided) on the first light emitting cell 200, the fourth light emitting cell 500, the first insulating layer IL1, the third connection electrode CE3, and/or the seventh connection electrode CE7. For example, the first conductive layer CL1 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the first conductive layer CL1 may include ITO, IZO, IGO, and/or the like. These materials may be used alone or in (e.g., any suitable) combination with each other.

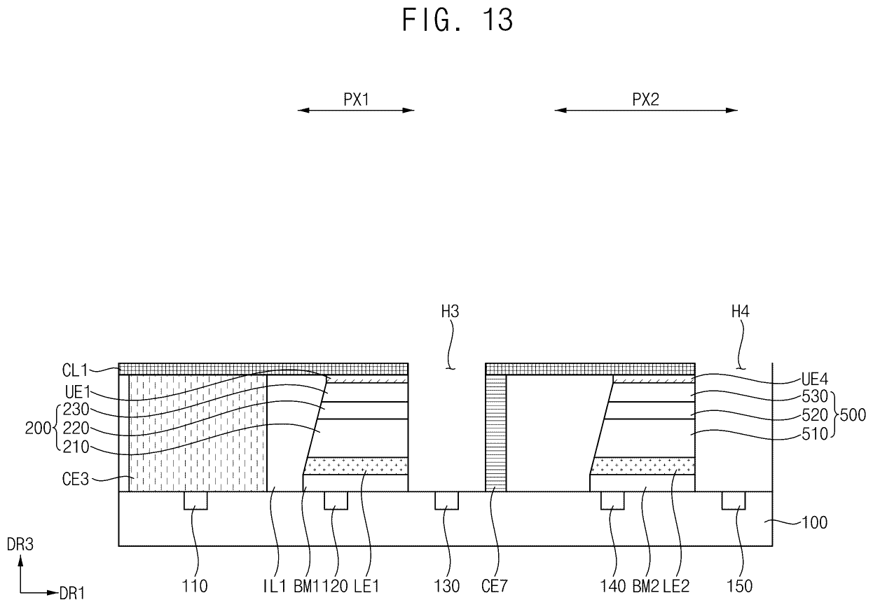

Referring to FIG. 13, a portion of the first conductive layer CL1, the first upper metal layer UE1, the first light emitting cell 200, the first lower metal layer LE1, and/or the first adhesive layer BM1 may be removed. For example, a portion of the first conductive layer CL1, the first upper metal layer UE1, the first light emitting cell 200, the first lower metal layer LE1, and/or the first adhesive layer BM1 may be removed to form (or provide) a third hole H3. The third hole H3 may at least partially overlap the first pixel area PX1 in the plan view. In addition, a portion of the first conductive layer CL1, the first upper metal layer UE1, the first light emitting cell 200, the first lower metal layer LE1, and/or the first adhesive layer BM1 may be removed to form (or provide) a fourth hole H4. The fourth hole H4 may at least partially overlap the second pixel area PX2 in the plan view.

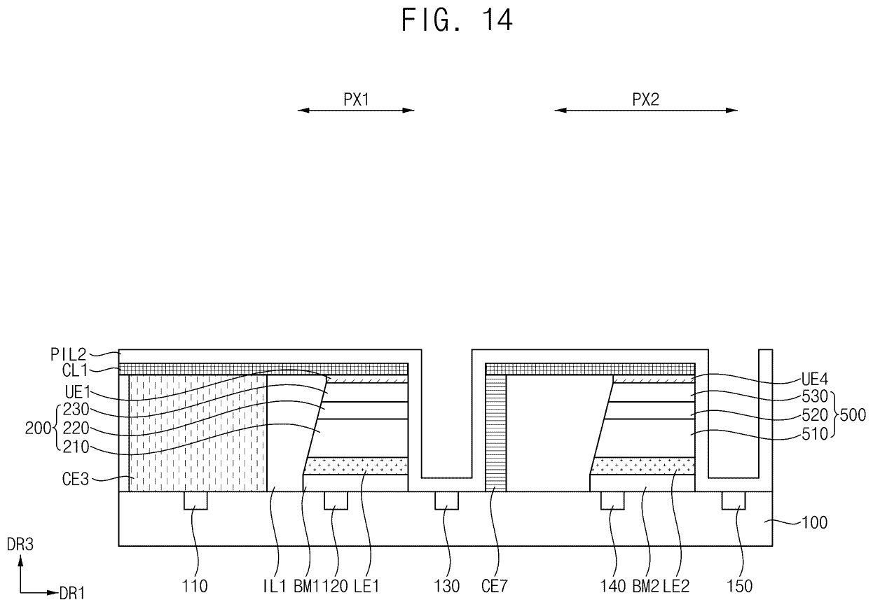

Referring to FIGS. 13 and 14, a second preliminary insulating layer PIL2 may be formed (or provided) on the first conductive layer CL1. The second preliminary insulating layer PIL2 may be formed (or provided) in the third hole H3 and/or the fourth hole H4. For example, the second preliminary insulating layer PIL2 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

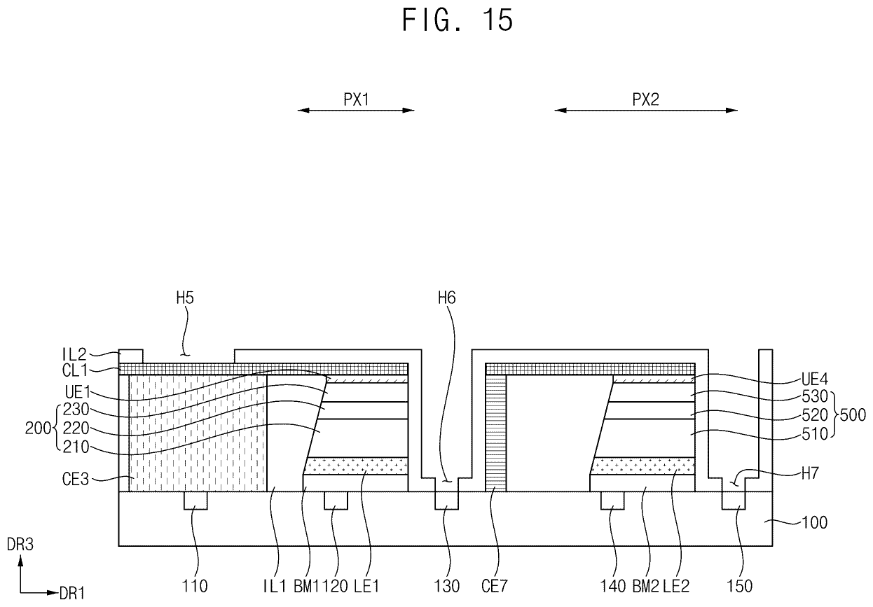

Referring to FIGS. 14 and 15, a portion of the second preliminary insulating layer PIL2 may be removed. For example, a fifth hole H5, a sixth hole H6, and/or a seventh hole H7 may be formed (or provided) in the second preliminary insulating layer PIL2. In one or more embodiments, the second insulating layer IL2 may be formed (or provided). The fifth hole H5 may at least partially overlap the third connection electrode CE3 in the plan view. The sixth hole H6 may overlap the third electrode 130 in the plan view. The seventh hole H7 may overlap the fifth electrode 150 in the plan view. The sixth hole H6 and the first opening OP1 of FIG. 2 may be substantially the same. The seventh hole H7 and the fourth opening OP4 of FIG. 2 may be substantially the same.

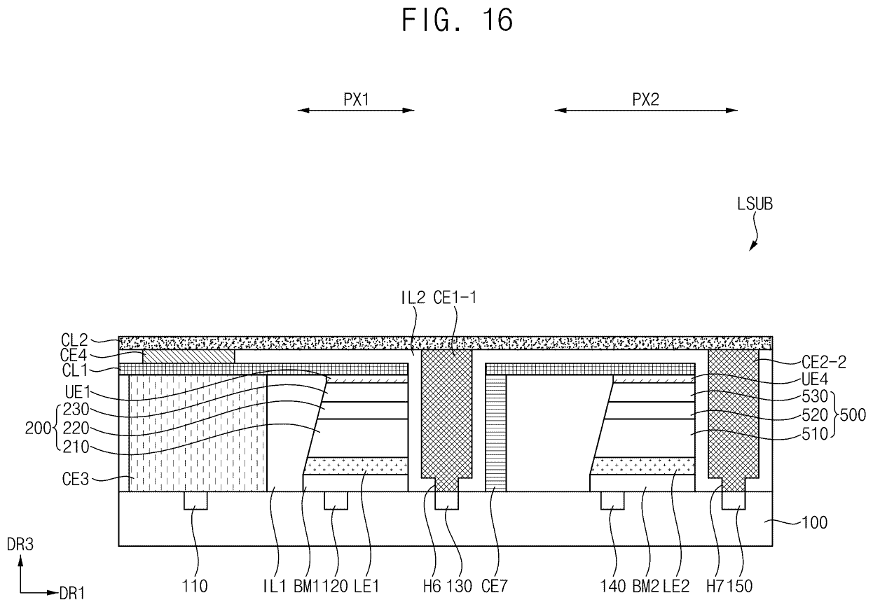

Referring to FIGS. 15 and 16, the 1-1 connection electrode CE1-1 may be formed (or provided) in the third hole (for example, the third hole H3 of FIG. 13) and/or the sixth hole H6. For example, the 1-1 connection electrode CE1-1 may be formed (or provided) through a damascene process. For example, the 1-1 connection electrode CE1-1 may be formed (or provided) to penetrate at least a portion of the first light emitting cell 200.

For example, the 1-1 connection electrode CE1-1 may include a metal, a metal nitride, a conductive (e.g., electrically conductive) metal oxide, a transparent conductive (e.g., electrically conductive) material, and/or the like. For example, the 1-1 connection electrode CE1-1 may include molybdenum, aluminum, chromium, titanium, gold, nickel, neodymium, copper, and/or the like. These materials may be used alone or in (e.g., any suitable) combination with each other.

The 2-2 connection electrode CE2-2 may be formed (or provided) in the fourth hole (for example, the fourth hole H4 of FIG. 13) and/or the seventh hole H7. For example, the 2-2 connection electrode CE2-2 may be formed (or provided) through a damascene process. For example, the 2-2 connection electrode CE2-2 may be formed (or provided) to penetrate at least a portion of the fourth light emitting cell 500.

For example, the 2-2 connection electrode CE2-2 may include a metal, a metal nitride, a conductive (e.g., electrically conductive) metal oxide, a transparent conductive (e.g., electrically conductive) material, and/or the like. For example, the 2-2 connection electrode CE2-2 may include molybdenum, aluminum, chromium, titanium, gold, nickel, neodymium, copper, and/or the like. These materials may be used alone or in (e.g., any suitable) combination with each other.

The fourth connection electrode CE4 may be formed (or provided) in the fifth hole H5. For example, the fourth connection electrode CE4 may be formed (or provided) through a damascene process. For example, the fourth connection electrode CE4 may include a metal, a metal nitride, a conductive (e.g., electrically conductive) metal oxide, a transparent conductive (e.g., electrically conductive) material, and/or the like. For example, the fourth connection electrode CE4 may include molybdenum, aluminum, chromium, titanium, gold, nickel, neodymium, copper, and/or the like. These materials may be used alone or in (e.g., any suitable) combination with each other.

For example, the 1-1 connection electrode CE1-1, the 2-2 connection electrode CE2-2, and/or the fourth connection electrode CE4 may be formed concurrently (e.g., simultaneously) and may include substantially the same material.

The second conductive layer CL2 may be formed (or provided) on the second insulating layer IL2, the fourth connection electrode CE4, the 1-1 connection electrode CE1-1, and/or the 2-2 connection electrode CE2-2. For example, the second conductive layer CL2 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the second conductive layer CL2 may include ITO, IZO, IGO, and/or the like. These materials may be used alone or in (e.g., any suitable) combination with each other.

In one or more embodiments, a lower display unit LSUB may be formed (or provided). For example, FIGS. 5, 6, 7, 8, 9, 10, 11, 12, 13, 14, 15, and 16 are cross-sectional views illustrating a series of processes in which the lower display unit LSUB may be formed (or provided). The lower display unit LSUB may include the circuit board 100, the first light emitting cell 200, the fourth light emitting cell 500, the first insulating layer IL1, the second insulating layer IL2, the 1-1 connection electrode CE1-1, the 2-2 connection electrode CE2-2, the third connection electrode CE3, the fourth connection electrode CE4, the seventh connection electrode CE7, the first conductive layer CL1, and/or the second conductive layer CL2.

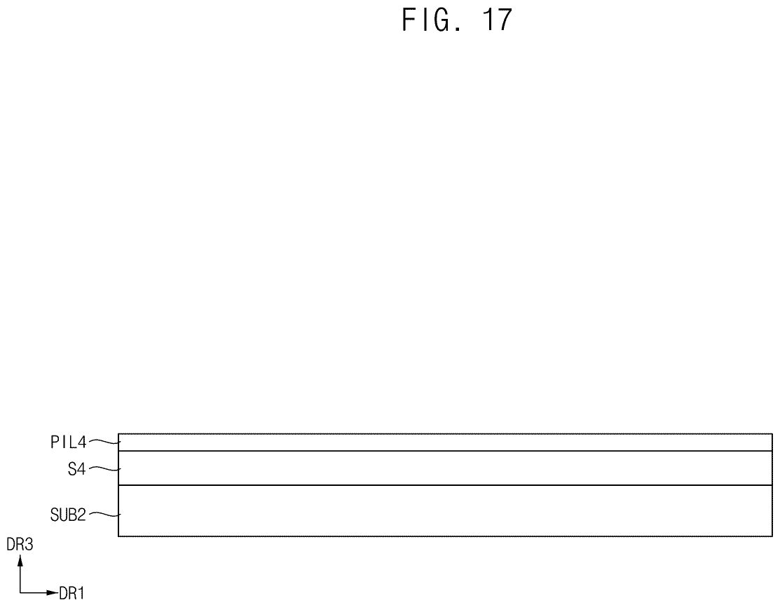

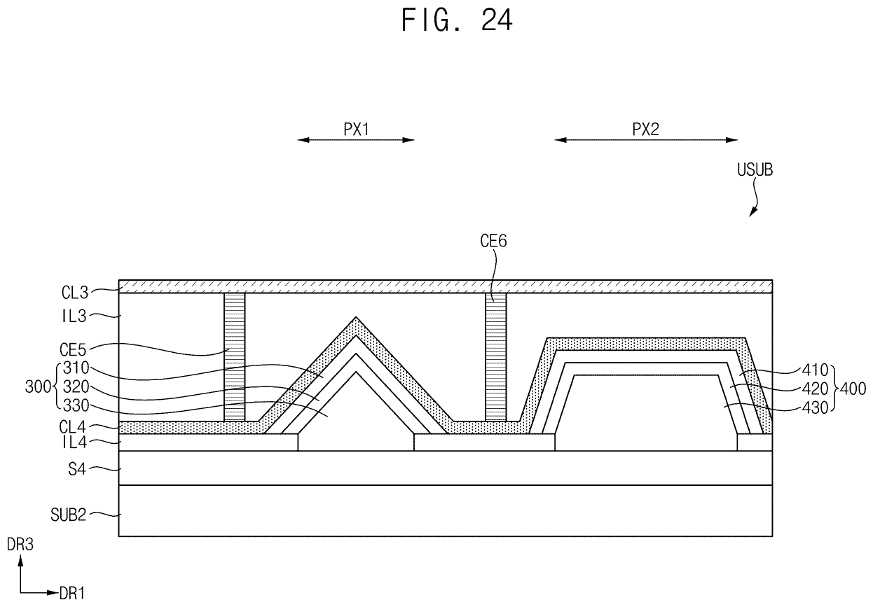

FIGS. 17, 18, 19, 20, 21, 22, 23, and 24 are cross-sectional views illustrating a series of processes in which an upper display unit (e.g., an upper display unit USUB of FIG. 24) may be formed (or provided).

Referring to FIG. 17, a third semiconductor layer S4 may be formed (or provided) on a second growth substrate SUB2. The second growth substrate SUB2 may be an epitaxial substrate. For example, the epitaxial substrate may include a silicon substrate, a silicon carbide substrate, a sapphire substrate, and/or the like. The third semiconductor layer S4 may be formed (or provided) by an epitaxial growth method.

In one or more embodiments, the third semiconductor layer S4 may include an n-type semiconductor layer. For example, the third semiconductor layer S4 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the third semiconductor layer S4 may include a GaN semiconductor material doped with the first conductive (e.g., electrically conductive) dopant.

A fourth preliminary insulating layer PIL4 may be formed (or provided) on the third semiconductor layer S4. For example, the fourth preliminary insulating layer PIL4 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

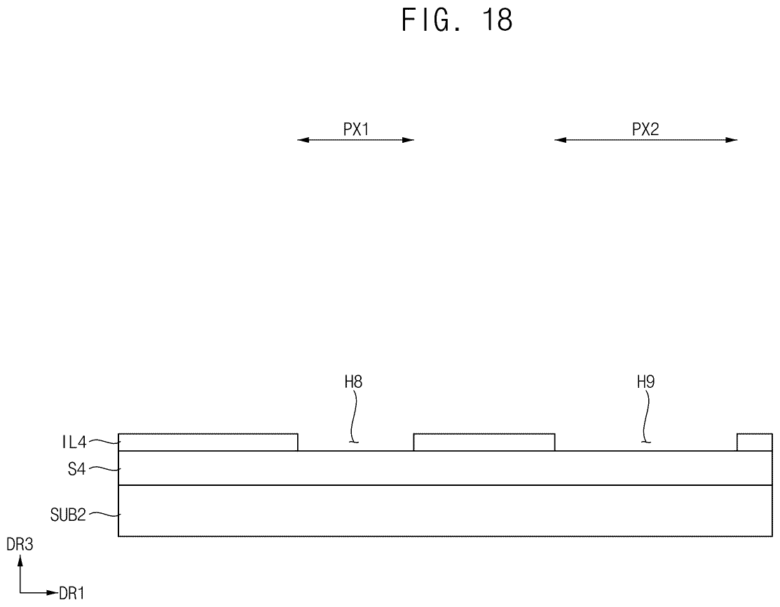

Referring to FIGS. 17 and 18, a portion of the fourth preliminary insulating layer PIL4 may be removed. For example, an eighth hole H8 and/or a ninth hole H9 may be formed (or provided) in the fourth preliminary insulating layer PIL4. In one or more embodiments, the fourth insulating layer IL4 may be formed (or provided). The eighth hole H8 may overlap the first pixel area PX1 in the plan view. The ninth hole H9 may overlap the second pixel area PX2 in the plan view.

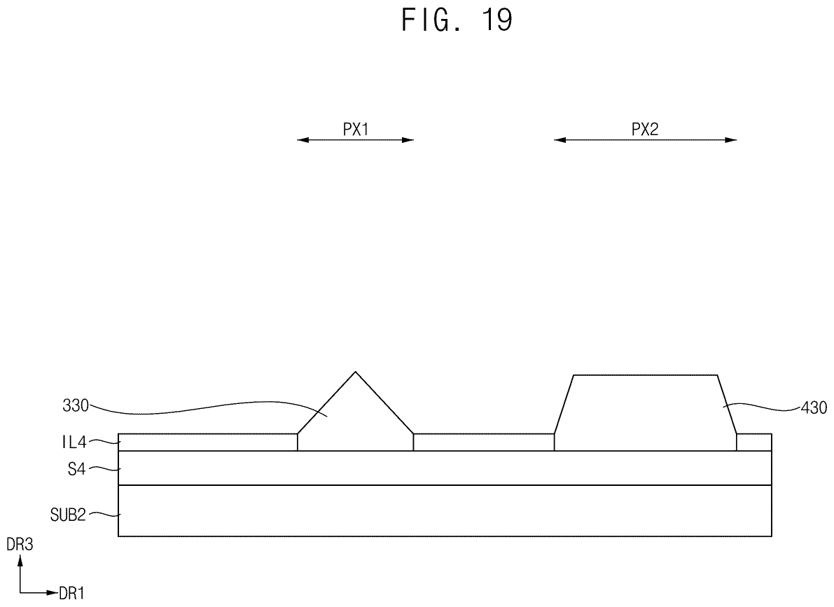

Referring to FIGS. 18 and 19, the 2-2 semiconductor layer 330 may be formed (or provided) in the first pixel area PX1. The 2-2 semiconductor layer 330 may have a shape vertically grown on the third semiconductor layer S4. The 2-2 semiconductor layer 330 may have one or more suitable shapes according to a cross-sectional shape of the eighth hole H8. For example, the 2-2 semiconductor layer 330 may have a shape in which a rectangle (e.g., a substantially rectangle) and a triangle (e.g., a substantially triangle) are sequentially stacked in the third direction DR3 in the cross-sectional view.

The 3-2 semiconductor layer 430 may be formed (or provided) in the second pixel area PX2. The 3-2 semiconductor layer 430 may have a shape vertically grown on the third semiconductor layer S4. The 3-2 semiconductor layer 430 may have one or more suitable shapes according to a cross-sectional shape of the ninth hole H9. For example, the 3-2 semiconductor layer 430 may have a shape in which a rectangular (e.g., a substantially rectangular) and a trapezoid (e.g., a substantially trapezoid) are sequentially stacked in the third direction DR3 in the cross-sectional view.

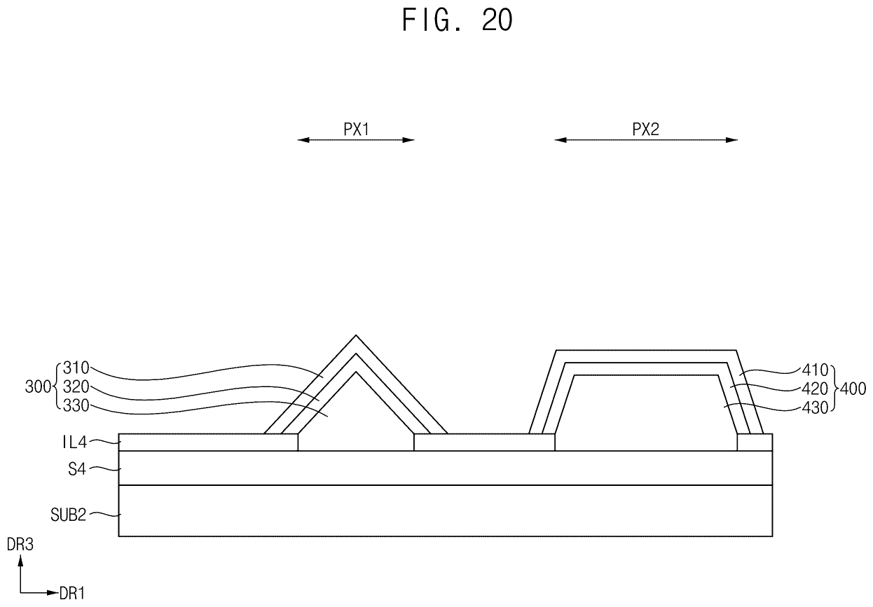

Referring to FIG. 20, the second active layer 320 may be formed (or provided) on the 2-2 semiconductor layer 330. For example, the second active layer 320 may be formed (or provided) in the first pixel area PX1. For example, the second active layer 320 may include a single well structure, a multi-well structure, a single quantum well structure, a multi-quantum well structure, a quantum dot structure, and/or a quantum line structure. For example, the second active layer 320 may include a multi-quantum well structure. In one or more embodiments, the second active layer 320 may include a structure in which a well layer and a barrier layer are alternately stacked. The well layer may include InGaN, and the barrier layer may include GaN and/or AlGaN, but embodiments of the present disclosure are not limited thereto.

The 2-1 semiconductor layer 310 may be formed (or provided) on the second active layer 320. For example, the 2-1 semiconductor layer 310 may be formed (or provided) in the first pixel area PX1. In one or more embodiments, the 2-1 semiconductor layer 310 may include a p-type semiconductor layer. For example, the 2-1 semiconductor layer 310 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 2-1 semiconductor layer 310 may include a GaN semiconductor material doped with the second conductive (e.g., electrically conductive) dopant.

The third active layer 420 may be formed (or provided) on the 3-2 semiconductor layer 430. For example, the third active layer 420 may be formed (or provided) in the second pixel area PX2. For example, the third active layer 420 may include a single well structure, a multi-well structure, a single quantum well structure, a multi-quantum well structure, a quantum dot structure, and/or a quantum line structure. For example, the third active layer 420 may include a multi-quantum well structure. In one or more embodiments, the third active layer 420 may include a structure in which a well layer and a barrier layer are alternately stacked.

The 3-1 semiconductor layer 410 may be formed (or provided) on the third active layer 420. For example, the 3-1 semiconductor layer 410 may be formed (or provided) in the second pixel area PX2. In one or more embodiments, the 3-1 semiconductor layer 410 may include a p-type semiconductor layer. For example, the 3-1 semiconductor layer 410 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 3-1 semiconductor layer 410 may include a GaN semiconductor material doped with the second conductive (e.g., electrically conductive) dopant.

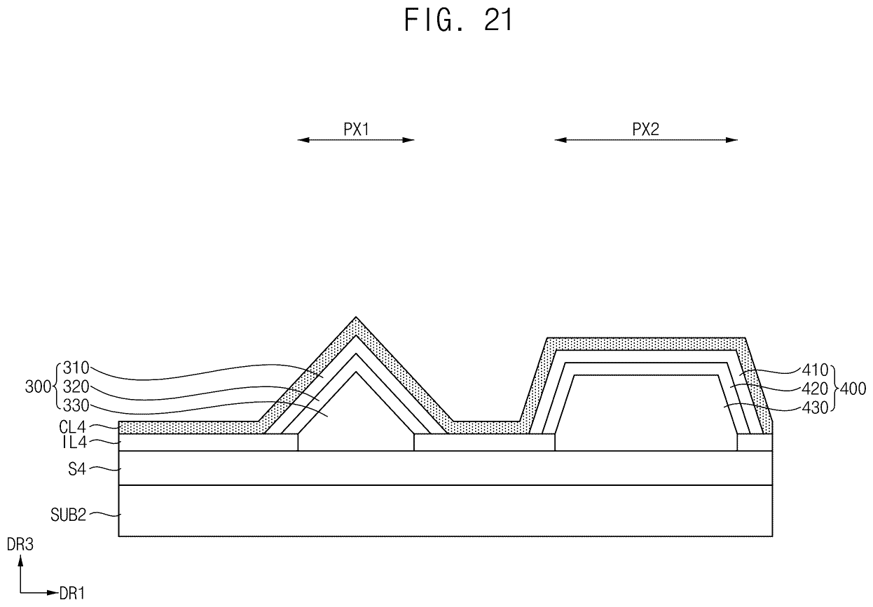

Referring to FIG. 21, the fourth conductive layer CL4 may be formed (or provided) on the fourth insulating layer IL4, the 2-1 semiconductor layer 310, and/or the 3-1 semiconductor layer 410. For example, the fourth conductive layer CL4 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the fourth conductive layer CL4 may include ITO, IZO, IGO, and/or the like. These materials may be used alone or in (e.g., any suitable) combination with each other.

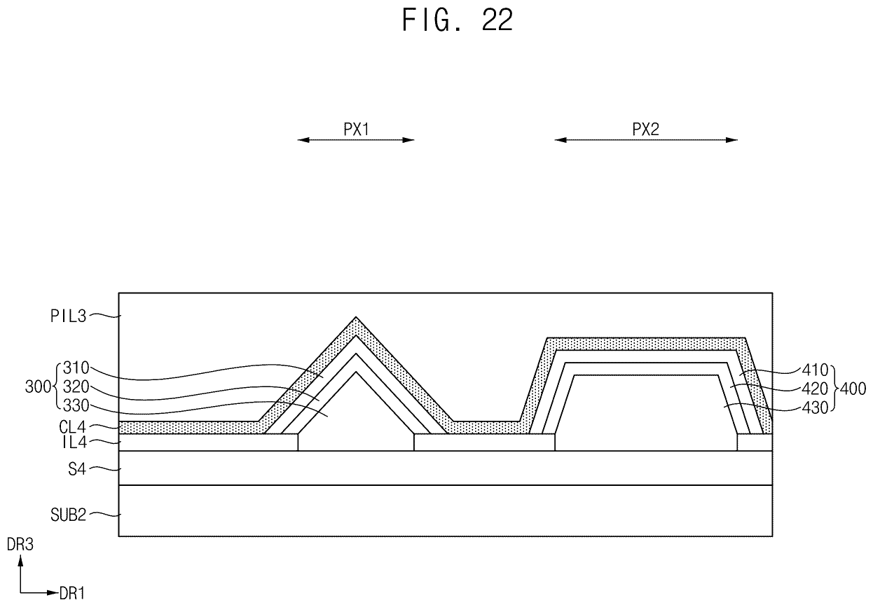

Referring to FIG. 22, a third preliminary insulating layer PIL3 may be formed (or provided) on the fourth conductive layer CL4. For example, the third preliminary insulating layer PIL3 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

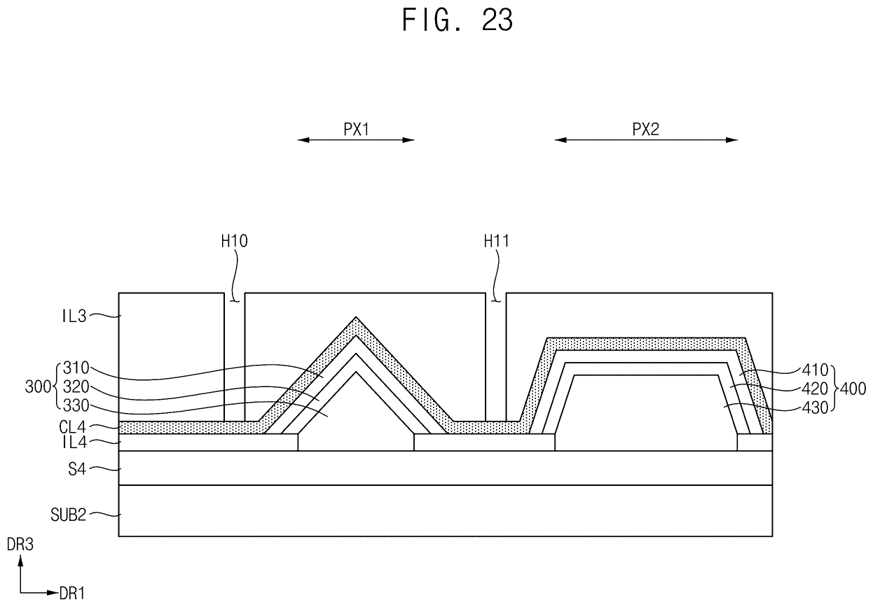

Referring to FIGS. 22 and 23, a portion of the third preliminary insulating layer PIL3 may be removed. For example, a tenth hole H10 and an eleventh hole H11 may be formed (or provided) in the third preliminary insulating layer PIL3. In one or more embodiments, the third insulating layer IL3 may be formed (or provided). The tenth hole H10 may be spaced and/or apart (e.g., spaced apart or separated) from the first pixel area PX1 in the direction opposite to the first direction DR1. The eleventh hole H11 may be formed (or provided) between the first pixel area PX1 and the second pixel area PX2.

Referring to FIGS. 23 and 24, the fifth connection electrode CE5 may be formed (or provided) in the tenth hole H10. For example, the fifth connection electrode CE5 may be formed (or provided) through a damascene process. For example, the fifth connection electrode CE5 may include a metal, a metal nitride, a conductive (e.g., electrically conductive) metal oxide, a transparent conductive (e.g., electrically conductive) material, and/or the like. For example, the fifth connection electrode CE5 may include molybdenum, aluminum, chromium, titanium, gold, nickel, neodymium, copper, and/or the like. These materials may be used alone or in (e.g., any suitable) combination with each other.

The sixth connection electrode CE6 may be formed (or provided) in the eleventh hole H11. For example, the sixth connection electrode CE6 may be formed (or provided) through a damascene process. For example, the sixth connection electrode CE6 may include a metal, a metal nitride, a conductive (e.g., electrically conductive) metal oxide, a transparent conductive (e.g., electrically conductive) material, and/or the like. For example, the sixth connection electrode CE6 may include molybdenum, aluminum, chromium, titanium, gold, nickel, neodymium, copper, and/or the like. These materials may be used alone or in (e.g., any suitable) combination with each other.

In one or more embodiments, the fifth connection electrode CE5 and/or the sixth connection electrode CE6 may be formed concurrently (e.g., simultaneously) and may include substantially the same material.

The third conductive layer CL3 may be formed (or provided) on the third insulating layer IL3, the fifth connection electrode CE5, and/or the sixth connection electrode CE6. For example, the third conductive layer CL3 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the third conductive layer CL3 may include ITO, IZO, IGO, and/or the like. These materials may be used alone or in (e.g., any suitable) combination with each other.

In one or more embodiments, the upper display unit USUB may be formed (or provided). The upper display unit USUB may include the second growth substrate SUB2, the third semiconductor layer S4, the second light emitting cell 300, the third light emitting cell 400, the third insulating layer IL3, the fifth connection electrode CE5, the sixth connection electrode CE6, and/or the third conductive layer CL3.

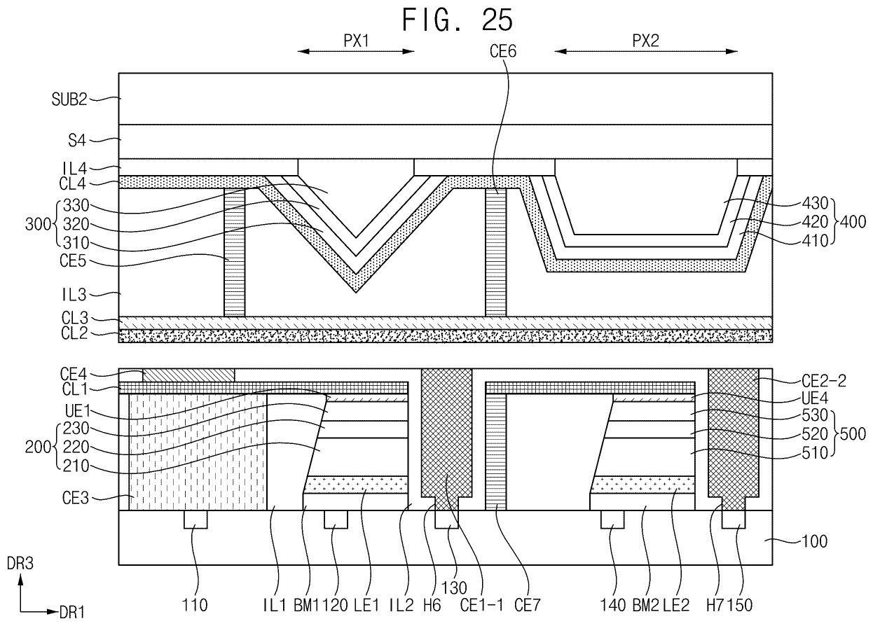

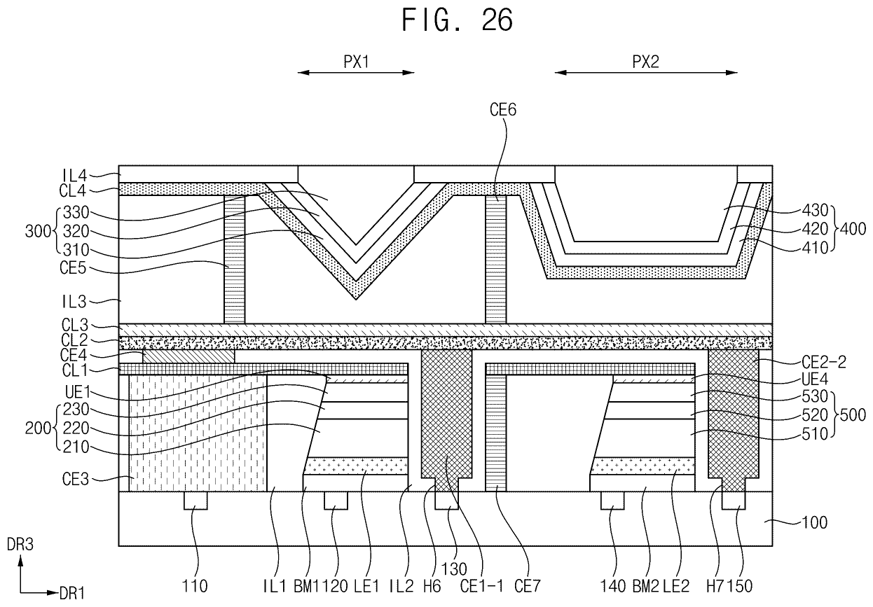

Referring to FIGS. 25 and 26, the upper display unit (e.g., the upper display unit USUB of FIG. 24) may be attached onto the lower display unit (e.g., the lower display unit LSUB of FIG. 16). For example, the upper display unit may be attached to the lower display unit in an inverted state such that the second conductive layer CL2 faces the lower display unit.

After the upper display unit is attached to the lower display unit, the second growth substrate SUB2 and/or the third semiconductor layer S4 may be removed.

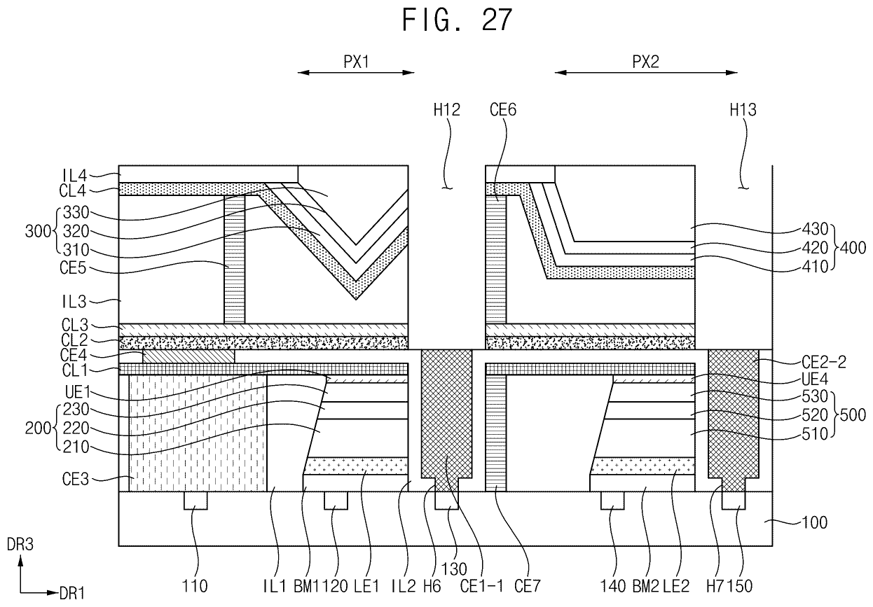

Referring to FIG. 27, a portion of the second light emitting cell 300, the fourth conductive layer CL4, the third insulating layer IL3, the third conductive layer CL3, the second conductive layer CL2, and/or the sixth connection electrode CE6 may be removed to form (or provide) a twelfth hole H12. For example, the twelfth hole H12 may at least partially overlap the first pixel area PX1 in the plan view. For example, the twelfth hole H12 may overlap the 1-1 connection electrode CE1-1 in the plan view.

A Portion of the third light emitting cell 400, the fourth conductive layer CL4, the third insulating layer IL3, the third conductive layer CL3, and/or the second conductive layer CL2 may be removed to form (or provide) a thirteenth hole H13. For example, the thirteenth hole H13 may at least partially overlap the second pixel area PX2 in the plan view. For example, the thirteenth hole H13 may at least partially overlap the 2-2 connection electrode CE2-2 in the plan view.

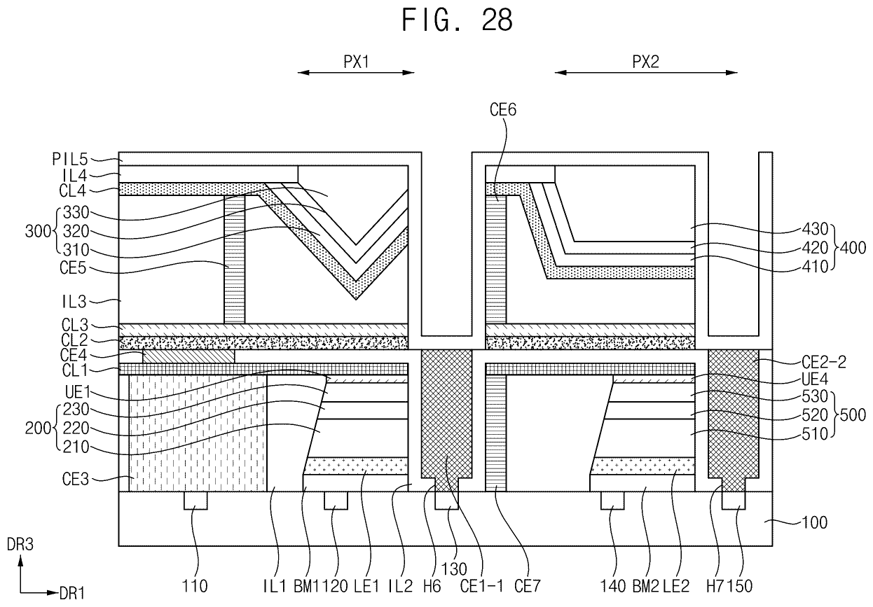

Referring to FIGS. 27 and 28, a fifth preliminary insulating layer PIL5 may be formed (or provided) on the fourth insulating layer IL4, the 2-2 semiconductor layer 330, and/or the 3-2 semiconductor layer 430. The fifth preliminary insulating layer PIL5 may be formed (or provided) in the twelfth hole H12 and/or the thirteenth hole H13. For example, the fifth preliminary insulating layer PIL5 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

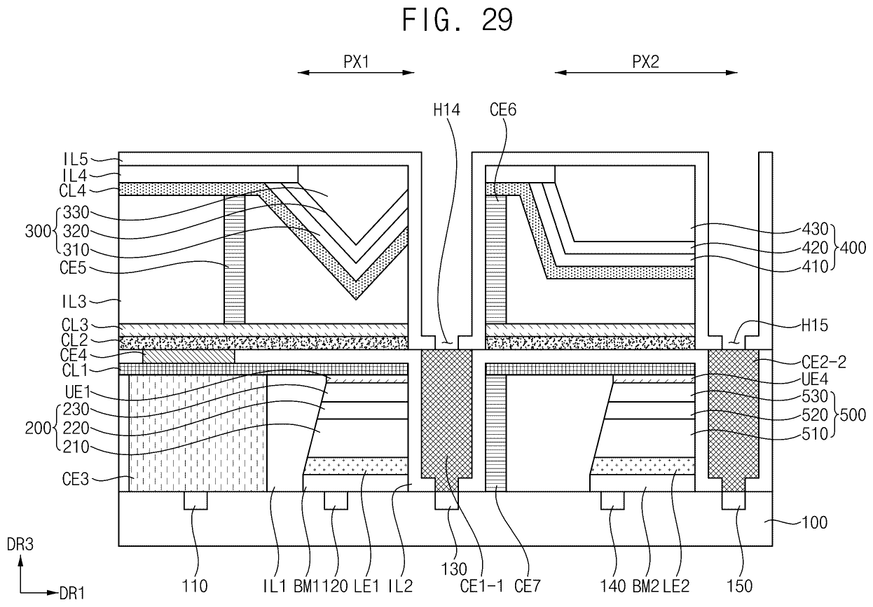

Referring to FIGS. 28 and 29, a portion of the fifth preliminary insulating layer PIL5 may be removed. For example, a fourteenth hole H14 and/or a fifteenth hole H15 may be formed (or provided) in the fifth preliminary insulating layer PIL5. In one or more embodiments, the fifth insulating layer IL5 may be formed (or provided). The fourteenth hole H14 and the second opening OP2 of FIG. 2 may be substantially the same. The fifteenth hole H15 and the second opening OP3 of FIG. 2 may be substantially the same.

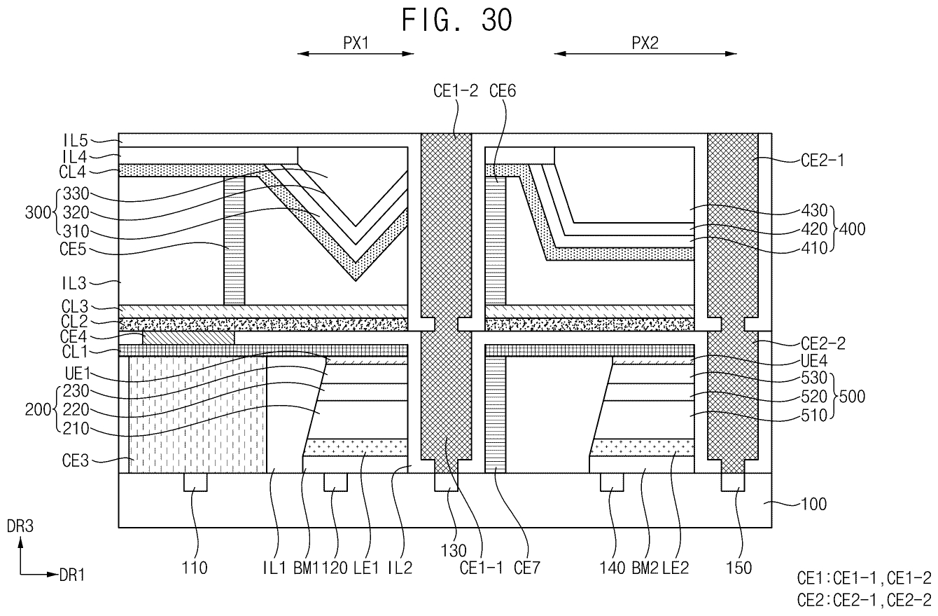

Referring to FIGS. 29 and 30, the 1-2 connection electrode CE1-2 may be formed (or provided) in the twelfth hole (for example, the twelfth hole H12 of FIG. 27) and/or the fourteenth hole H14. The 1-2 connection electrode CE1-2 may be formed (or provided) to overlap the 1-1 connection electrode CE1-1 in the plan view. For example, the 1-2 connection electrode CE1-2 may be formed (or provided) to penetrate at least a portion of the second light emitting cell 300.

For example, the 1-2 connection electrode CE1-2 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the 1-2 connection electrode CE1-2 may include ITO, IZO, IGO, and/or the like. These materials may be used alone or in (e.g., any suitable) combination with each other.

The 2-1 connection electrode CE2-1 may be formed (or provided) in the thirteenth hole (for example, the thirteenth hole H13 of FIG. 27) and/or the fifteenth hole H15. The 2-1 connection electrode CE2-1 may be formed (or provided) to overlap the 2-2 connection electrode CE2-2 in the plan view. For example, the 2-1 connection electrode CE2-1 may be formed (or provided) to penetrate at least a portion of the third light emitting cell 400.

For example, the 2-1 connection electrode CE2-1 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the 2-1 connection electrode CE2-1 may include ITO, IZO, IGO, and/or the like. These materials may be used alone or in (e.g., any suitable) combination with each other.

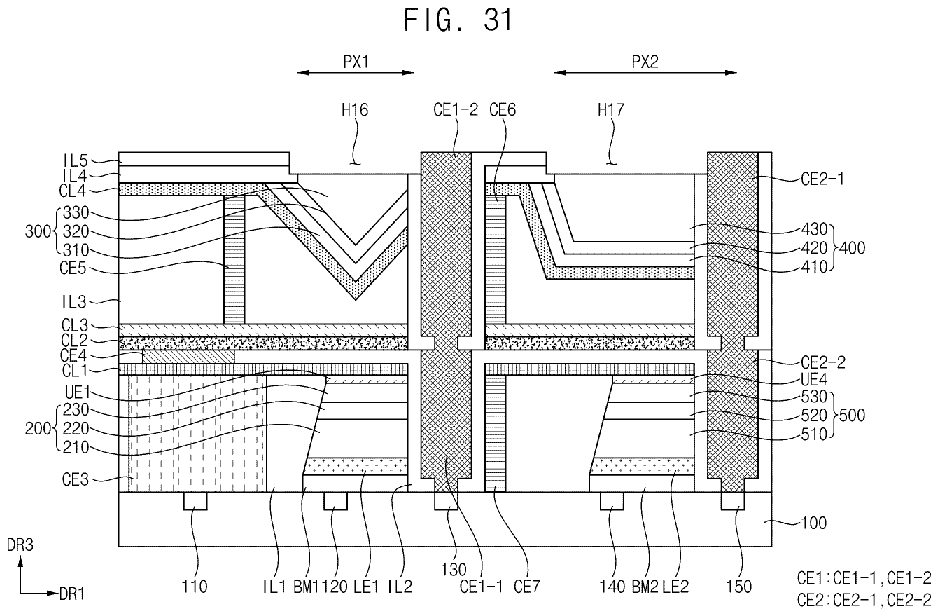

Referring to FIG. 31, a portion of the fourth insulating layer IL4 and/or the fifth insulating layer IL5 may be removed. For example, a sixteenth hole H16 and/or a seventeenth hole H17 may be formed (or provided) in the fourth insulating layer IL4 and/or the fifth insulating layer IL5. The sixteenth hole H16 may overlap the first pixel area PX1 in the plan view. The seventeenth hole H17 may overlap the second pixel area PX2 if (e.g., when) viewed in the plan view.

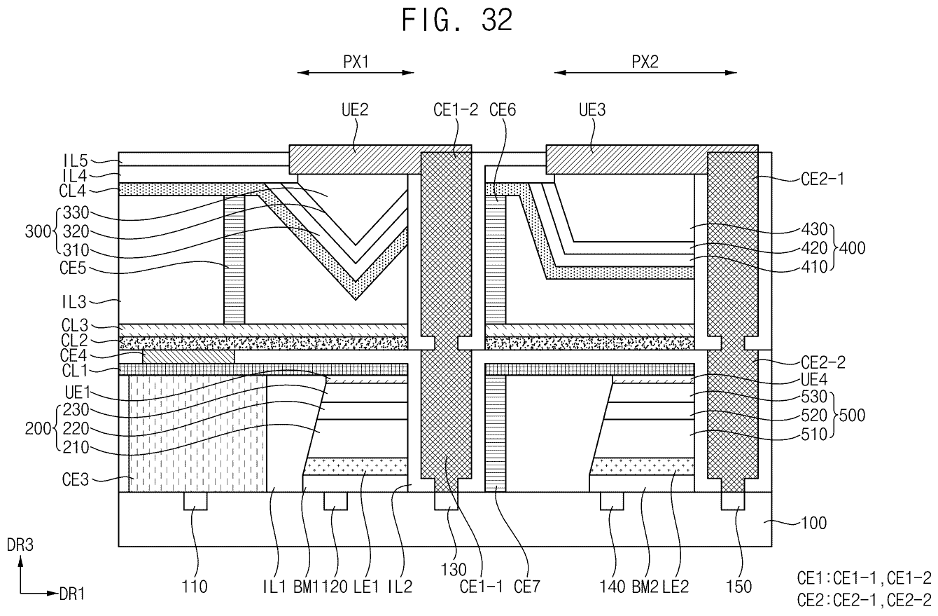

Referring to FIGS. 31 and 32, the second upper metal layer UE2 may be formed (or provided) in the sixteenth hole H16. For example, the second upper metal layer UE2 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the second upper metal layer UE2 may include ITO, IZO, IGO, and/or the like. These materials may be used alone or in (e.g., any suitable) combination with each other.

The third upper metal layer UE3 may be formed (or provided) in the seventeenth hole H17. For example, the third upper metal layer UE3 may include a metal, a metal nitride, a conductive (e.g., electrically conductive) metal oxide, a transparent conductive (e.g., electrically conductive) material, and/or the like. These materials may be used alone or in (e.g., any suitable) combination with each other. For example, the third upper metal layer UE3 may include ITO, IZO, IGO, and/or the like. These materials may be used alone or in (e.g., any suitable) combination with each other.

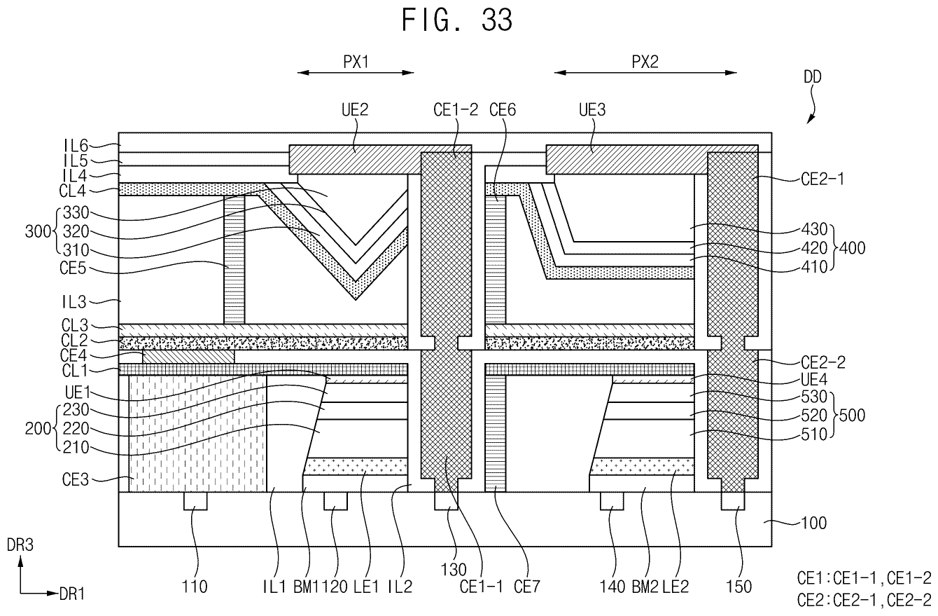

Referring to FIG. 33, the sixth insulating layer IL6 may be formed (or provided) on the fifth insulating layer IL5, the second upper metal layer UE2, and/or the third upper metal layer UE3. For example, the sixth insulating layer IL6 may include silicon oxide (SiOₓ), silicon nitride (SiNₓ), silicon oxynitride (SiOₓN_{y}), silicon oxycarbide (SiOₓC_{y}), aluminum oxide (AlOₓ), aluminum nitride (AlNₓ), zirconium oxide (ZrOₓ), hafnium oxide (HfOₓ), titanium oxide (TiOₓ), and/or the like. These materials may be used alone or in (e.g., any suitable) combination with each other.

A method of manufacturing the display device DD according to one or more embodiments may include a step (e.g., act or task) of monolithically attaching the upper display unit (e.g., the upper display unit USUB of FIG. 24) onto the lower display unit (e.g., the lower display unit LSUB of FIG. 16). The process of attaching the upper display unit onto the lower display unit may be referred to as a wafer-to-wafer (W2 W) process. A method of manufacturing the display device DD according to one or more embodiments may include a single wafer-to-wafer bonding process. For example, through a single wafer-to-wafer bonding process, the second light emitting cell 300 and/or the third light emitting cell 400 may be attached onto the first light emitting cell 200 and/or the fourth light emitting cell 500, and, In one or more embodiments, the display device DD may be manufactured. In one or more embodiments, a manufacturing process of the display device DD may be suitably simplified or modified. As mentioned above, the first light emitting cell 200 may be to emit the first light, the second light emitting cell 300 may be to emit the second light, and the third light emitting cell 400 may be to emit the third light. For example, the first light emitting cell 200 may be to emit red light, the second light emitting cell 300 may be to emit blue light, and the third light emitting cell 400 may be to emit green light. According to one or more embodiments, the display device DD in which an RGB full-color system is implemented may be manufactured through a single wafer-to-wafer process.

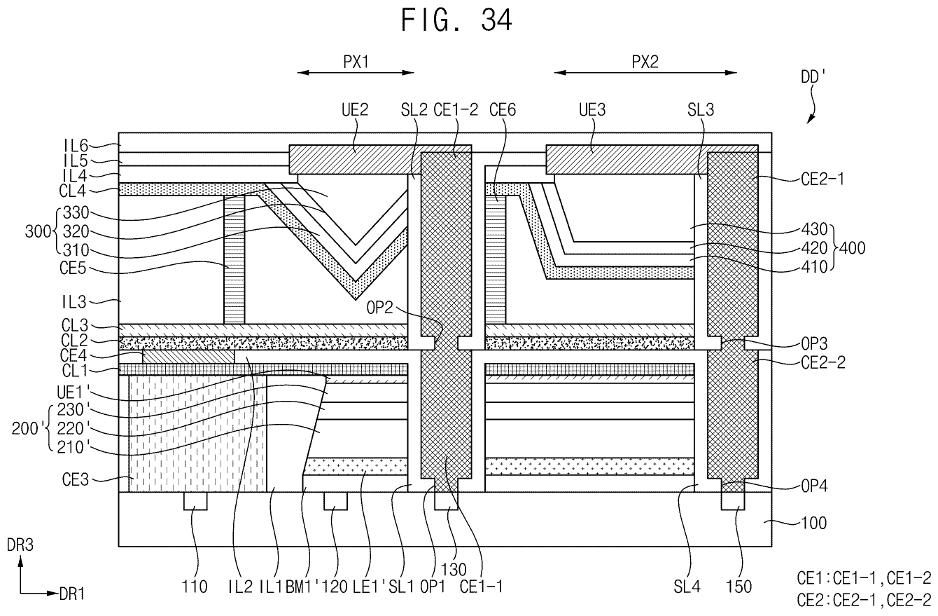

FIG. 34 is a cross-sectional view illustrating a display device according to one or more embodiments.

A display device DD′ described with reference to FIG. 34 may be substantially the same as or substantially similar to the display device DD described with reference to FIG. 2, except for configurations or arrangements of a first light emitting cell 200′, a first lower metal layer LE1, a first adhesive layer BM1′, and/or a first upper metal layer UE1′. Therefore, overlapping descriptions will not be provided or suitably simplified or modified.

Referring to FIG. 34, a first light emitting cell 200′ may be arranged (or provided) on the circuit board 100. The first light emitting cell 200′ may include a 1-1 semiconductor layer 210′, a first active layer 220′, and/or a 1-2 semiconductor layer 230′. The first active layer 220′ may be arranged (or provided) on the 1-1 semiconductor layer 210′. The 1-2 semiconductor layer 230′ may be arranged (or provided) on the first active layer 220′. For example, the first light emitting cell 200′ may be to emit first light. In one or more embodiments, the first light may be red light.

In one or more embodiments, the first light emitting cell 200′ may be continuously (e.g., substantially continuously) arranged (or provided) over the first pixel area PX1 and/or the second pixel area PX2. For example, the first light emitting cell 200′ may be continuously (e.g., substantially continuously) arranged (or provided) over the first pixel area PX1 and/or the second pixel area PX2 except for a portion where the 1-1 connection electrode CE1-1 is arranged (or provided) and/or a portion where the 2-2 connection electrode CE2-2 is arranged (or provided).

A first lower metal layer LE1′ may be arranged (or provided) under the first light emitting cell 200′. The first lower metal layer LE1′ may be continuously (e.g., substantially continuously) arranged (or provided) over the first pixel area PX1 and/or the second pixel area PX2. For example, the first lower metal layer LE1′ may be continuously (e.g., substantially continuously) arranged (or provided) over the first pixel area PX1 and/or the second pixel area PX2 except for a portion where the 1-1 connection electrode CE1-1 is arranged (or provided) and/or a portion where the 2-2 connection electrode CE2-2 is arranged (or provided).

A first adhesive layer BM1′ may be arranged (or provided) under the first lower metal layer LE1′. The first adhesive layer BM1′ may be continuously (e.g., substantially continuously) arranged (or provided) over the first pixel area PX1 and/or the second pixel area PX2. For example, the first adhesive layer BM1′ may be continuously (e.g., substantially continuously) arranged (or provided) over the first pixel area PX1 and/or the second pixel area PX2 except for a portion where the 1-1 connection electrode CE1-1 is arranged (or provided) and/or a portion where the 2-2 connection electrode CE2-2 is arranged (or provided).

A first upper metal layer UE1′ may be arranged (or provided) on the first light emitting cell 200′. The first upper metal layer UE1′ may be continuously (e.g., substantially continuously) arranged (or provided) over the first pixel area PX1 and/or the second pixel area PX2. For example, the first upper metal layer UE1′ may be continuously (e.g., substantially continuously) arranged (or provided) over the first pixel area PX1 and/or the second pixel area PX2 except for a portion where the 1-1 connection electrode CE1-1 is arranged (or provided) and/or a portion where the 2-2 connection electrode CE2-2 is arranged (or provided).

The 1-1 semiconductor layer 210′ may be electrically connected to (or coupled to) the second electrode 120. For example, the 1-1 semiconductor layer 210′ may be electrically connected to (or coupled to) the second electrode 120 through the first lower metal layer LE1′ and/or the first adhesive layer BM1′. The display device DD′ according to one or more embodiments may not include (e.g., may exclude) the fourth electrode 140 and/or the seventh connection electrode CE7 included in the display device DD of FIG. 2.

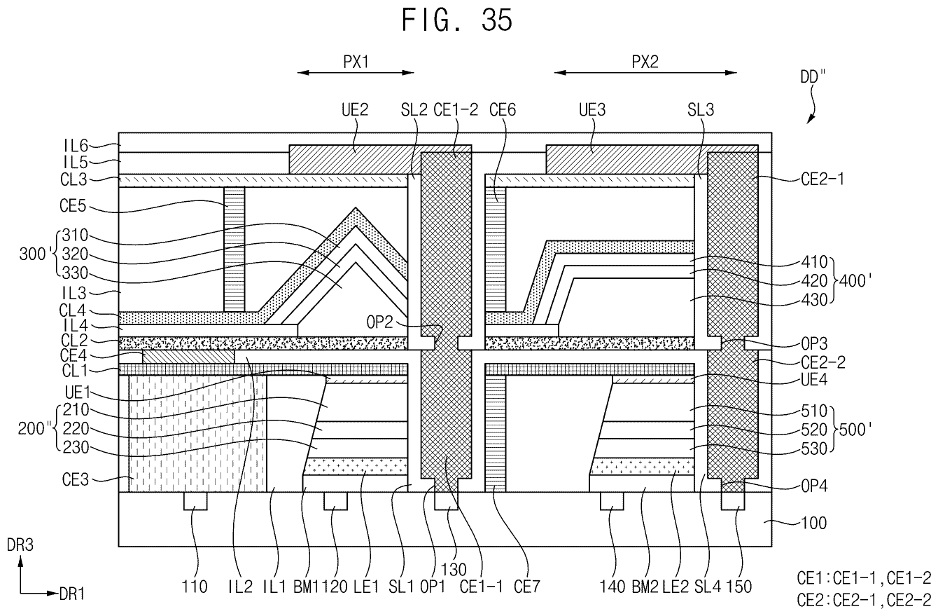

FIG. 35 is a cross-sectional view illustrating a display device according to one or more embodiments.

A display device DD″ described with reference to FIG. 35 may be substantially the same as or substantially similar to the display device DD described with reference to FIG. 2, except for configurations or arrangements of a first light emitting cell 200″, a second light emitting cell 300′, a third light emitting cell 400′ and/or a fourth light emitting cell 500′. In one or more embodiments, overlapping description will not be provided or suitably simplified or modified.

Referring to FIG. 35, a first light emitting cell 200″ may include a 1-1 semiconductor layer 210, a first active layer 220, and/or a 1-2 semiconductor layer 230. For example, the first active layer 220 may be arranged (or provided) on the 1-2 semiconductor layer 230. In addition, the 1-1 semiconductor layer 210 may be arranged (or provided) on the first active layer 220.

The 1-2 semiconductor layer 230 may include a p-type semiconductor layer. For example, the 1-2 semiconductor layer 230 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 1-2 semiconductor layer 230 may include a GaN semiconductor material doped with the second conductive (e.g., electrically conductive) dopant.

The first active layer 220 may include a single well structure, a multi-well structure, a single quantum well structure, a multi-quantum well structure, a quantum dot structure, and/or a quantum line structure. For example, the first active layer 220 may include a multi-quantum well structure. In one or more embodiments, the first active layer 220 may include a structure in which a well layer and a barrier layer are alternately stacked. The well layer may include InGaN, and the barrier layer may include GaN and/or AlGaN, but embodiments of the present disclosure are not limited thereto.

The 1-1 semiconductor layer 210 may include an n-type semiconductor layer. For example, the 1-1 semiconductor layer 210 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the 1-1 semiconductor layer 210 may include a GaN semiconductor material doped with the first conductive (e.g., electrically conductive) dopant.

A second light emitting cell 300′ may include a 2-1 semiconductor layer 310, a second active layer 320, and/or a 2-2 semiconductor layer 330. For example, the second active layer 320 may be arranged (or provided) on the 2-2 semiconductor layer 330. In addition, the 2-1 semiconductor layer 310 may be arranged (or provided) on the second active layer 320.

The 2-2 semiconductor layer 330 may include an n-type semiconductor layer. For example, the 2-2 semiconductor layer 330 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the 2-2 semiconductor layer 330 may include a GaN semiconductor material doped with the first conductive (e.g., electrically conductive) dopant.

The second active layer 320 may include a single well structure, a multi-well structure, a single quantum well structure, a multi-quantum well structure, a quantum dot structure, and/or a quantum line structure. For example, the second active layer 320 may include a multi-quantum well structure. In one or more embodiments, the second active layer 320 may include a structure in which a well layer and a barrier layer are alternately stacked. The well layer may include InGaN, and the barrier layer may include GaN and/or AlGaN, but embodiments of the present disclosure are not limited thereto.

The 2-1 semiconductor layer 310 may include a p-type semiconductor layer. For example, the 2-1 semiconductor layer 310 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 2-1 semiconductor layer 310 may include a GaN semiconductor material doped with the second conductive (e.g., electrically conductive) dopant.

A third light emitting cell 400′ may include a 3-1 semiconductor layer 410, a third active layer 420, and/or a 3-2 semiconductor layer 430. For example, the third active layer 420 may be arranged (or provided) on the 3-2 semiconductor layer 430. In addition, the 3-1 semiconductor layer 410 may be arranged (or provided) on the third active layer 420.

The 3-2 semiconductor layer 430 may include an n-type semiconductor layer. For example, the 3-2 semiconductor layer 430 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the 3-2 semiconductor layer 430 may include a GaN semiconductor material doped with the first conductive (e.g., electrically conductive) dopant.

The third active layer 420 may include a single well structure, a multi-well structure, a single quantum well structure, a multi-quantum well structure, a quantum dot structure, and/or a quantum line structure. For example, the third active layer 420 may include a multi-quantum well structure. In one or more embodiments, the third active layer 420 may include a structure in which a well layer and a barrier layer are alternately stacked. The well layer may include InGaN, and the barrier layer may include GaN and/or AlGaN, but embodiments of the present disclosure are not limited thereto.

The 3-1 semiconductor layer 410 may include a p-type semiconductor layer. For example, the 3-1 semiconductor layer 410 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 3-1 semiconductor layer 410 may include a GaN semiconductor material doped with the second conductive (e.g., electrically conductive) dopant.

A fourth light emitting cell 500′ may include a 4-1 semiconductor layer 510, a fourth active layer 520, and/or a 4-2 semiconductor layer 530. For example, the fourth active layer 520 may be arranged (or provided) on the 4-2 semiconductor layer 530. In addition, the 4-1 semiconductor layer 510 may be arranged (or provided) on the fourth active layer 520.

The 4-2 semiconductor layer 530 may include a p-type semiconductor layer. For example, the 4-2 semiconductor layer 530 may include a semiconductor material, such as GaN, InAlGaN, AlGaN, InGaN, AlN, InN, and/or the like, and may include a p-type semiconductor layer doped with the second conductive (e.g., electrically conductive) dopant (e.g., the p-type dopant), such as Zn, Fe, Mg, Be, Cd, Ag, C, Hg, Li, Ca, and/or the like. For example, the 4-2 semiconductor layer 530 may include a GaN semiconductor material doped with the second conductive (e.g., electrically conductive) dopant.

The fourth active layer 520 may include a single well structure, a multi-well structure, a single quantum well structure, a multi-quantum well structure, a quantum dot structure, and/or a quantum line structure. For example, the fourth active layer 520 may include a multi-quantum well structure. In one or more embodiments, the fourth active layer 520 may include a structure in which a well layer and a barrier layer are alternately stacked. The well layer may include InGaN, and the barrier layer may include GaN and/or AlGaN, but embodiments of the present disclosure are not limited thereto.

The 4-1 semiconductor layer 510 may include an n-type semiconductor layer. For example, the 4-1 semiconductor layer 510 may include a semiconductor material, such as GaN, InAlGaN, AlGaN, InGaN, AlN, InN, and/or the like, and may include an n-type semiconductor layer doped with the first conductive (e.g., electrically conductive) dopant (e.g., the n-type dopant), such as Si, Sn, Te, Se, S, O, Ti, Ge, and/or the like. For example, the 4-1 semiconductor layer 510 may include a GaN semiconductor material doped with the first conductive (e.g., electrically conductive) dopant.

The fourth insulating layer IL4 may be arranged (or provided) on the second conductive layer CL2. The fourth conductive layer CL4 may be arranged (or provided) on the fourth insulating layer IL4, the second light emitting cell 300′, and/or the third light emitting cell 400′. The third conductive layer CL3 may be arranged (or provided) on the third insulating layer IL3. The fifth insulating layer IL5 may be arranged (or provided) on the third conductive layer CL3. The sixth insulating layer IL6 may be arranged (or provided) on the fifth insulating layer IL5.

The 1-2 semiconductor layer 230 may be electrically connected to (or coupled to) the second electrode 120 through the first lower metal layer LE1 and/or the first adhesive layer BM1. In one or more embodiments, the second electrode 120 may be an anode of the first light emitting cell 200″.

The 2-1 semiconductor layer 310 may be electrically connected to (or coupled to) the third electrode 130 through the fourth conductive layer CL4, the fifth connection electrode CE5, the third conductive layer CL3, the second upper metal layer UE2, and/or the first connection electrode CE1. In one or more embodiments, the third electrode 130 may be an anode of the second light emitting cell 300′.

The 3-1 semiconductor layer 410 may be electrically connected to (or coupled to) the fifth electrode 150 through the fourth conductive layer CL4, the sixth connection electrode CE6, the third upper metal layer UE3, and/or the second connection electrode CE2. In one or more embodiments, the fifth electrode 150 may be an anode of the third light emitting cell 400′.

The 4-2 semiconductor layer 530 may be electrically connected to (or coupled to) the fourth electrode 140 through the second lower metal layer LE2 and/or the second adhesive layer BM2. In one or more embodiments, the fourth electrode 140 may be an anode of the fourth light emitting cell 500′.

The 1-1 semiconductor layer 210 may be connected to (or coupled to) the first electrode 110 through the third connection electrode CE3, the first conductive layer CL1, and/or the first upper metal layer UE1. The 2-2 semiconductor layer 330 may be electrically connected to (or coupled to) the first electrode 110 through the second conductive layer CL2, the fourth connection electrode CE4, the first conductive layer CL1, and/or the third connection electrode CE3. The 3-2 semiconductor layer 430 may be electrically connected to (or coupled to) the first electrode 110 through the second conductive layer CL2, the fourth connection electrode CE4, the first conductive layer CL1, and/or the third connection electrode CE3. The 4-1 semiconductor layer 510 may be electrically connected to (or coupled to) the first electrode 110 through the fourth upper metal layer UE4, the first conductive layer CL1, and/or the third connection electrode CE3.

In one or more embodiments, the first electrode 110 may be a cathode electrode of each of the first light emitting cell 200″, the second light emitting cell 300′, the third light emitting cell 400′ and the fourth light emitting cell 500′.

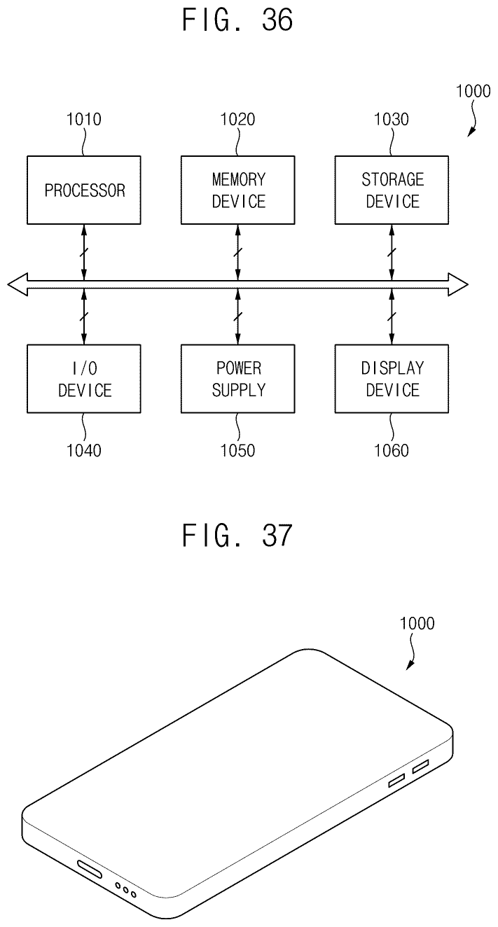

FIG. 36 is a block diagram illustrating an electronic device according to one or more embodiments. FIG. 37 is a diagram illustrating an example in which the electronic device of FIG. 36 is implemented as a smart phone.

Referring to FIGS. 36 and 37, an electronic device 1000 may include a processor 1010, a memory device 1020, a storage device 1030, an input/output device 1040, a power supply 1050, and a display device 1060. In one or more embodiments, the display device 1060 may be the display device DD of FIG. 1. In one or more embodiments, the electronic device 1000 may further include one or more suitable ports capable of communicating with a video card, a sound card, a memory card, a USB device, and/or the like.

According to one or more embodiments, as illustrated in FIG. 37, the electronic device 1000 may be implemented as a smartphone. However, this is exemplary, and the electronic device 1000 may be implemented as one or more suitable devices according to one or more embodiments. For example, the electronic device 1000 may be implemented as a mobile phone, a video phone, a smart pad, a smart watch, a tablet PC, a vehicle navigation device, a computer monitor, a notebook computer, a head mounted display device, and/or the like.

The processor 1010 may be a microprocessor, a central processing unit, an application processor, and/or the like. The processor 1010 may be connected to one or more other components through an address bus, a control bus, a data bus, and/or the like. In one or more embodiments, the processor 1010 may also be connected to an expansion bus, such as a peripheral component interconnect (“PCI”) bus.

The memory device 1020 may store data necessary for the operation of the electronic device 1000. For example, the memory device 1020 may include a nonvolatile memory device and/or a volatile memory device. Examples of the nonvolatile memory device may include an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and/or the like. Example of the volatile memory device may include a dynamic random access memory (“DRAM”) device, a static random access memory (“SRAM”) device, a mobile DRAM device, and/or the like.

The storage device 1030 may include a solid state drive (“SSD”), a hard disk drive (“HDD”), a CD-ROM, and/or the like.

The input/output device 1040 may include an input mean, such as a keyboard, a keypad, a touch pad, a touch screen, a mouse, and/or the like, and an output mean, such as a speaker, a printer, and/or the like. In one or more embodiments, the display device 1060 may be included in the input/output device 1040.

The power supply 1050 may supply power necessary for the operation of the electronic device 1000. For example, the power supply 1050 may supply power necessary for the operation of the display device 1060.

The display device 1060 may be connected to one or more other components through buses and/or other communication links.

The present disclosure may be applied to one or more suitable display devices. For example, the present disclosure may be applicable to one or more suitable display devices, such as display devices for vehicles, ships, and aircraft, portable communication devices, display devices for exhibition or information transmission, medical display devices, and/or the like.

A person of ordinary skill in the art, in view of the present disclosure in its entirety, would appreciate that each suitable feature of the one or more embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

A display device, a device for manufacturing the display device, and/or any other relevant devices or components according to one or more embodiments of the present disclosure as described herein may be implemented utilizing any suitable hardware, firmware (e.g. an application-specific integrated circuit), software, or a combination of software, firmware, and hardware. For example, the one or more components of the device may be formed or provided on one integrated circuit (IC) chip or on separate IC chips. Further, the one or more components of the device may be implemented on a flexible printed circuit film, a tape carrier package (TCP), a printed circuit board (PCB), or formed or provided on one substrate. Further, the one or more components of the device may be a process or thread, running on one or more processors, in one or more computing devices, executing computer program instructions and interacting with other system components for performing the one or more functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the present disclosure.

The foregoing is illustrative of one or more embodiments of the present disclosure and is not to be construed as limiting thereof. Although certain embodiments of the present disclosure have been described, those skilled in the art will readily appreciate that one or more suitable modifications may be possible in one or more embodiments without materially departing from the novel teachings and features of the present disclosure. Accordingly, all such modifications are intended to be included within the scope of the present disclosure as claimed in the claims. Therefore, it is to be understood that the foregoing is illustrative of one or more suitable embodiments and is not to be construed as limited to the specific embodiments disclosed, and that modifications to the disclosed embodiments, as well as one or more embodiments, are intended to be included within the scope of the appended claims and equivalents thereof.

What is claimed is:

1. A light emitting element comprising:
a first light emitting cell in a first pixel area, wherein the first light emitting cell is to emit first light;
a second light emitting cell in the first pixel area on the first light emitting cell, wherein the second light emitting cell is to emit second light having a wavelength different from a wavelength of the first light; and
a third light emitting cell in a second pixel area spaced from the first pixel area in a plan view, wherein the third light emitting cell is to emit third light having a wavelength different from each of the wavelength of the first light and the wavelength of the second light.

2. The light emitting element as claimed in claim 1, wherein the third light emitting cell is on the first light emitting cell.

3. The light emitting element as claimed in claim 2, further comprising:
a fourth light emitting cell in the second pixel area and under the third light emitting cell, wherein the fourth light emitting cell is to emit the first light.

4. The light emitting element as claimed in claim 1, wherein the first light emitting cell comprises:
a 1-1 semiconductor layer;
a first active layer on the 1-1 semiconductor layer; and
a 1-2 semiconductor layer on the first active layer.

5. The light emitting element as claimed in claim 4, wherein the second light emitting cell comprises:
a 2-1 semiconductor layer;
a second active layer on the 2-1 semiconductor layer; and
a 2-2 semiconductor layer on the second active layer.

6. The light emitting element as claimed in claim 5, wherein:
each of the 1-1 semiconductor layer and the 2-2 semiconductor layer comprises an n-type semiconductor layer, and
each of the 1-2 semiconductor layer and the 2-1 semiconductor layer comprises a p-type semiconductor layer.

7. The light emitting element as claimed in claim 6, further comprising:
a connection electrode electrically connected to each of the 1-2 semiconductor layer and the 2-1 semiconductor layer.

8. A light emitting element comprising:
a first light emitting cell in a first pixel area, the first light emitting cell being to emit first light, wherein the first light emitting cell comprises:
a 1-1 semiconductor layer comprising an n-type semiconductor layer;
a first active layer on the 1-1 semiconductor layer; and
a 1-2 semiconductor layer on the first active layer, the 1-2 semiconductor layer comprising a p-type semiconductor layer;
a second light emitting cell in the first pixel area on the first light emitting cell, the second light emitting cell being to emit second light having a wavelength different from a wavelength of the first light, wherein the second light emitting cell comprises:
a 2-1 semiconductor layer comprising a p-type semiconductor layer;
a second active layer on the 2-1 semiconductor layer; and
a 2-2 semiconductor layer on the second active layer, the 2-2 semiconductor comprising an n-type semiconductor layer; and
a third light emitting cell in a second pixel area spaced from the first pixel area in a plan view, the third light emitting cell being to emit third light having a wavelength different from each of the wavelength of the first light and the wavelength of the second light, wherein the third light emitting cell comprises:
a 3-1 semiconductor layer comprising a p-type semiconductor layer;
a third active layer on the 3-1 semiconductor layer; and
a 3-2 semiconductor layer on the third active layer, the 3-2 semiconductor layer comprising an n-type semiconductor layer.

9. The light emitting element as claimed in claim 8, wherein the third light emitting cell is on the first light emitting cell.

10. The light emitting element as claimed in claim 8, further comprising:
a connection electrode electrically connected to each of the 1-2 semiconductor layer and the 2-1 semiconductor layer.

11. The light emitting element as claimed in claim 8, further comprising:
a fourth light emitting cell in the second pixel area and under the third light emitting cell, wherein the fourth light emitting cell is to emit the first light.

12. The light emitting element as claimed in claim 11, wherein the fourth light emitting cell comprises:
a 4-1 semiconductor layer comprising an n-type semiconductor layer;
a fourth active layer on the 4-1 semiconductor layer; and
a 4-2 semiconductor layer on the fourth active layer, the 4-2 semiconductor layer comprising a p-type semiconductor layer.

13. The light emitting element as claimed in claim 8, wherein the first light emitting cell is continuously provided over the first pixel area and the second pixel area.

14. A light emitting element comprising:
a first light emitting cell in a first pixel area, the first light emitting cell being to emit first light, wherein the first light emitting cell comprises:
a 1-1 semiconductor layer comprising a p-type semiconductor layer;
a first active layer on the 1-1 semiconductor layer; and
a 1-2 semiconductor layer on the first active layer, the 1-2 semiconductor layer comprising an n-type semiconductor layer;
a second light emitting cell in the first pixel area on the first light emitting cell, the second light emitting cell being to emit second light having a wavelength different from a wavelength of the first light, wherein the second light emitting cell comprises:
a 2-1 semiconductor layer comprising an n-type semiconductor layer;
a second active layer on the 2-1 semiconductor layer; and
a 2-2 semiconductor layer on the second active layer, the 2-2 semiconductor layer comprising a p-type semiconductor layer; and
a third light emitting cell in a second pixel area spaced from the first pixel area in a plan view, the third light emitting cell being to emit third light having a wavelength different from each of the wavelength of the first light and the wavelength of the second light, wherein the third light emitting cell comprises:
a 3-1 semiconductor layer comprising an n-type semiconductor layer;
a third active layer on the 3-1 semiconductor layer; and
a 3-2 semiconductor layer on the third active layer, the 3-2 semiconductor layer comprising a p-type semiconductor layer.

15. The light emitting element as claimed in claim 14, wherein the third light emitting cell is on the first light emitting cell.

16. The light emitting element as claimed in claim 15, further comprising:
a connection electrode electrically connected to each of the 1-2 semiconductor layer and the 2-1 semiconductor layer.

17. The light emitting element as claimed in claim 14, further comprising:
a fourth light emitting cell in the second pixel area and under the third light emitting cell, wherein the fourth light emitting cell is to emit the first light.

18. The light emitting element as claimed in claim 17, wherein the fourth light emitting cell comprises:
a 4-1 semiconductor layer comprising a p-type semiconductor layer;
a fourth active layer on the 4-1 semiconductor layer; and
a 4-2 semiconductor layer on the fourth active layer, the 4-2 semiconductor layer comprising an n-type semiconductor layer.

19. A display device comprising:
a circuit board; and
a light emitting element on the circuit board,
wherein the light emitting element comprises:
a first light emitting cell in a first pixel area, the first light emitting cell being to emit first light;
a second light emitting cell in the first pixel area on the first light emitting cell, the second light emitting cell being to emit second light having a wavelength different from a wavelength of the first light; and
a third light emitting cell in a second pixel area spaced from the first pixel area in a plan view, the third light emitting cell being to emit third light having a wavelength different from each of the wavelength of the first light and the wavelength of the second light.

20. The display device as claimed in claim 19, wherein the third light emitting cell is on the first light emitting cell.

21. The display device as claimed in claim 19, wherein the first light emitting cell comprises:
a 1-1 semiconductor layer;
a first active layer on the 1-1 semiconductor layer; and
a 1-2 semiconductor layer on the first active layer.

22. The display device as claimed in claim 21, wherein the second light emitting cell comprises:
a 2-1 semiconductor layer;
a second active layer on the 2-1 semiconductor layer; and
a 2-2 semiconductor layer on the second active layer.

23. The display device as claimed in claim 22, wherein:
each of the 1-1 semiconductor layer and the 2-2 semiconductor layer comprises an n-type semiconductor layer, and
each of the 1-2 semiconductor layer and the 2-1 semiconductor layer comprises a p-type semiconductor layer.

24. The display device as claimed in claim 23, wherein the circuit board comprises a first electrode, a second electrode, and a third electrode, and
the 1-2 semiconductor layer and the 2-1 semiconductor layer are electrically connected to the first electrode.

25. The display device as claimed in claim 24, wherein:
the 1-1 semiconductor layer is electrically connected to the second electrode, and
the 2-2 semiconductor layer is electrically connected to the third electrode.

26. The display device as claimed in claim 25, wherein the 2-2 semiconductor layer is electrically connected to the third electrode through a connection electrode penetrating at least a portion of each of the first light emitting cell and the second light emitting cell.

27. A method of manufacturing a display device, the method comprising:
forming a first light emitting cell in a first pixel area on the circuit board, wherein the first light emitting cell is to emit first light;
forming a second light emitting cell in the first pixel area on a first growth substrate, wherein the second light emitting cell is to emit second light having a wavelength different from a wavelength of the first light;
forming a third light emitting cell in a second pixel area spaced from the first pixel area in a plan view on the first growth substrate, wherein the third emitting cell is to emit third light having a wavelength different from each of the wavelength of the first light and the wavelength of the second light; and
attaching the second light emitting cell and the third light emitting cell on the first light emitting cell.

28. The method as claimed in claim 27, wherein the forming of the first light emitting cell comprises:
forming a first semiconductor layer on the second growth substrate;
forming an active layer on the first semiconductor layer;
forming a second semiconductor layer on the active layer;
removing the second growth substrate; and
removing a portion of the first semiconductor layer, the active layer, and the second semiconductor layer not overlapping the first pixel area in the plan view on the circuit board.

29. The method as claimed in claim 27, further comprising:
forming a first connection electrode penetrating at least a portion of the first light emitting cell and electrically connected to an electrode in the circuit board; and
forming a second connection electrode penetrating at least a portion of the second light emitting cell and electrically connected to the first connection electrode.

30. The method as claimed in claim 29, wherein the forming of the second light emitting cell comprises:
forming a preliminary insulating layer on the first growth substrate;
forming an insulating layer by removing a portion of the preliminary insulating layer overlapping the first pixel area and the second pixel area;
forming a first semiconductor layer in the first pixel area on the first growth substrate;
forming an active layer on the first semiconductor layer; and
forming a second semiconductor layer on the active layer.

31. The method as claimed in claim 30, wherein the second semiconductor layer is electrically connected to the second connection electrode.

32. An electronic device comprising:
a circuit board;
a light emitting element on the circuit board; and
a memory device configured to store memory,
wherein the light emitting element comprises:
a first light emitting cell in a first pixel area, the first light emitting cell being to emit first light;
a second light emitting cell in the first pixel area on the first light emitting cell, the second light emitting cell being to emit second light having a wavelength different from a wavelength of the first light; and
a third light emitting cell in a second pixel area spaced from the first pixel area in a plan view, the third light emitting cell being to emit third light having a wavelength different from each of the wavelength of the first light and the wavelength of the second light.
